(19) United States
(12) Patent Application Publication
(10) Pub. No.: US 2026/0101655 A1
(43) Pub. Date: Apr. 9, 2026

(54) DISPLAY SUBSTRATE AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Cuicui LIANG, Beijing (CN); Weifeng ZHOU, Beijing (CN); Chao YANG, Beijing (CN); Jiandong BAO, Beijing (CN); Bin WANG, Beijing (CN)

(21) Appl. No.: 18/993,535

(22) PCT Filed: May 14, 2024
(86) PCT No.: PCT/CN2024/093011

§ 371 Date: Dec. 14, 2025

(30) Foreign Application Priority Data
Jun. 20, 2023 (CN) 202310736483.0

(51) Int. Cl. H10K 59/38; H10K 59/12; H10K 59/121; H10K 59/122; H10K 59/123; H10K 59/35

(52) U.S. Cl. CPC H10K 59/38; H10K 59/1201; H10K 59/1213; H10K 59/1216; H10K 59/122; H10K 59/123; H10K 59/352

(57) ABSTRACT

The present disclosure provides a display substrate and a display apparatus, and belongs to the field of display technology. The display substrate includes a base substrate, a plurality of pixel units arranged in an array on the base substrate, and a color filter layer on a side of the pixel units facing away from the base substrate. Each pixel unit includes a plurality of pixel drive circuits and a plurality of light-emitting devices on the base substrate, with each light-emitting device electrically connected to one of the pixel drive circuits to form one subpixel. The color filter layer includes a plurality of color filter blocks, with each color filter block corresponding to one of the light-emitting devices. Orthographic projections of pixel openings of at least part of the light-emitting devices on the base substrate each have a circular contour shape; and/or, orthographic projections of pixel openings of at least part of the light-emitting devices on the base substrate each have a symmetrical contour shape enclosed by a plurality of arc-shaped parts and straight sides alternately arranged, and at least two of the arc-shaped parts correspond to a same angle.

### TECHNICAL FIELD

The present disclosure relates to the field of display technology, and specifically relates to a display substrate and a display apparatus.

### BACKGROUND

With the rapid development of the display industry, the organic light-emitting diode (OLED) display apparatus, as one of the most common display devices now, has gained lots of attention and achieved great development in the field of display technology.

As an important component of a display apparatus, a display substrate typically has pixels arranged in various modes, such as real RGB (conventional), Pentile, Delta and the like, each of which has its advantages and disadvantages. Real RGB can achieve the best display effect, and in the conventional real RGB pixel structure, pixel drive circuits and light-emitting devices (i.e., red light-emitting devices R, green light-emitting devices G or blue light-emitting devices B) are arranged in one-to-one correspondence. A diffraction pattern of a real RGB based COE (CF on EN, color filter on encapsulation) product typically has a cross structure, as shown in FIG. 1, which is a schematic diagram of the diffraction pattern of a real RGB+COE product, and in which color separation can be clearly perceived and thus is not acceptable by users.

### SUMMARY

To solve the technical problems in the existing art, the present disclosure provides a display substrate and a display apparatus.

In a first aspect, a technical solution adopted to solve the technical problem of the present disclosure is a display substrate, including a base substrate, a plurality of pixel units arranged in an array on the base substrate, and a color filter layer on a side of the pixel units facing away from the base substrate; wherein
each pixel unit includes a plurality of pixel drive circuits and a plurality of light-emitting devices on the base substrate, with each light-emitting device electrically connected to one of the pixel drive circuits to form one subpixel; and the color filter layer includes a plurality of color filter blocks, with each color filter block corresponding to one of the light-emitting devices; and
orthographic projections of pixel openings of at least part of the light-emitting devices on the base substrate each have a circular contour shape; and/or, orthographic projections of pixel openings of at least part of the light-emitting devices on the base substrate each have a symmetrical contour shape enclosed by a plurality of arc-shaped parts and straight sides alternately arranged, and at least two of the arc-shaped parts correspond to a same angle.

In some embodiments, a plurality of subpixels are provided, including a first subpixel, a second subpixel, and a third subpixel; the first subpixel includes a first light-emitting device; the second subpixel includes a second light-emitting device; and the third subpixel includes a third light-emitting device and a fourth light-emitting device; and
for the plurality of pixel units arranged in an array, first light-emitting devices and second light-emitting devices are alternately arranged in a column direction to form multiple columns of first light-emitting device groups; and third light-emitting devices and fourth light-emitting devices are alternately arranged in the column direction to form multiple columns of second light-emitting device groups.

In some embodiments, orthographic projections of pixel openings of the first, second, third and fourth light-emitting devices on the base substrate each have a circular contour shape.

In some embodiments, for one of the pixel units, the first subpixel has an aperture ratio A, the second subpixel has an aperture ratio B, and the third subpixel has an aperture ratio C; and A:B:C is one of 1:(1.7 to 2.2):(1.4 to 2).

In some embodiments, the third light-emitting device has the same aperture ratio as the fourth light-emitting device.

In some embodiments, each pixel unit has an aperture ratio in a range from 10% to 55%.

In some embodiments, a plurality of subpixels are provided, including a first subpixel, a second subpixel, and a third subpixel; the first subpixel includes a first light-emitting device; the second subpixel includes a second light-emitting device and a fifth light-emitting device; and the third subpixel includes a third light-emitting device and a fourth light-emitting device; and
for the plurality of pixel units arranged in an array, first light-emitting devices and second subpixels are alternately arranged in a column direction to form multiple columns of first light-emitting device groups; and third light-emitting devices and fourth light-emitting devices are alternately arranged in the column direction to form multiple columns of second light-emitting device groups; and
an extension line of a connection line between center points of the second light-emitting device and the fifth light-emitting device forms an angle in a range of 0° to 90° with an extension line of a connection line between center points of the third light-emitting device and the fourth light-emitting device.

In some embodiments, orthographic projections of pixel openings of the first, second, third, fourth and fifth light-emitting devices on the base substrate each have a circular contour shape.

In some embodiments, the display substrate further includes a first conductive layer on a side of the pixel drive circuits facing away from the base substrate, and a pixel defining layer on a side of the first conductive layer facing away from the base substrate;
each light-emitting device includes a pixel opening penetrating through the pixel defining layer, and a first electrode formed on a side of the pixel defining layer close to the pixel drive circuit, and an emission layer and a second electrode at least in the pixel opening;
the first conductive layer includes the first electrode of each light-emitting device; and
for the third subpixel, the first electrode of the third light-emitting device is electrically connected to the first electrode of the fourth light-emitting device.

In some embodiments, the first electrode of the third light-emitting device and the first electrode of the fourth light-emitting device are connected into an integral structure.

In some embodiments, the first electrode of the third light-emitting device is disconnected from the first electrode of the fourth light-emitting device; and
for the third subpixel, the pixel drive circuit includes a drive transistor and a first connection electrode electrically connected to the drive transistor; the first connection electrode includes a first main body part, and a first branch part and a second branch part each electrically connected to the first main body part; and the first branch part is electrically connected to the first electrode of the third light-emitting device, while the second branch part is electrically connected to the first electrode of the fourth light-emitting device.

In some embodiments, for the second subpixel, the first electrode of the second light-emitting device is electrically connected to the first electrode of the fifth light-emitting device.

In some embodiments, the first electrode of the second light-emitting device and the first electrode of the fifth light-emitting device are connected into an integral structure.

In some embodiments, the first electrode of the second light-emitting device is disconnected from the first electrode of the fifth light-emitting device; and
for the second subpixel, the pixel drive circuit includes a drive transistor and a second connection electrode electrically connected to the drive transistor; the second connection electrode includes a second main body part, and a third branch part and a fourth branch part each electrically connected to the second main body part; and the third branch part is electrically connected to the first electrode of the second light-emitting device, while the fourth branch part is electrically connected to the first electrode of the fifth light-emitting device.

In some embodiments, the plurality of pixel units include a first pixel unit and a second pixel unit, and first pixel units and second pixel units are alternately arranged in each of a row direction and a column direction;
each of the first pixel unit and the second pixel unit includes a first subpixel, a second subpixel, and a third subpixel; the first subpixel includes a first light-emitting device, the second subpixel includes a second light-emitting device, and the third subpixel includes a third light-emitting device;
for the first pixel unit, the first light-emitting device and the second light-emitting device are located in a same column, which is a column adjacent to a column where the third light-emitting device is located;
for the second pixel unit, the first light-emitting device and the second light-emitting device are located in a same row, which is a row adjacent to a row where the third light-emitting device is located; and
a connection line between center points of the first and second light-emitting devices in the first pixel unit is a first line segment, while a connection line between center points of the first and second light-emitting devices in the second pixel unit is a second line segment; and an extending direction of the first line segment is perpendicular to an extending direction of the second line segment.

In some embodiments, orthographic projections of pixel openings of the first and second light-emitting devices on the base substrate each have a circular contour shape; and
an orthographic projection of a pixel opening of the third light-emitting device on the base substrate has an elliptical contour shape.

In some embodiments, for the first pixel unit, an extending direction of the first line segment is perpendicular to an extending direction of a minor axis corresponding to the contour of the pixel opening of the third light-emitting device; and
for the second pixel unit, an extending direction of the second line segment is perpendicular to the extending direction of the minor axis corresponding to the contour of the pixel opening of the third light-emitting device.

In some embodiments, the display substrate further includes a semiconductor layer on the base substrate, a second conductive layer on a side of the semiconductor layer facing away from the base substrate, a third conductive layer on a side of the second conductive layer facing away from the base substrate, and a fourth conductive layer on a side of the second conductive layer close to the third conductive layer;
each pixel drive circuit includes at least a plurality of thin film transistors and a storage capacitor;
an active layer of each thin film transistor is located in the semiconductor layer;
gates of at least part of the thin film transistors and a first plate of the storage capacitor are located in the second conductive layer; and
a second plate of the storage capacitor is located in the third conductive layer; and
control signal lines of at least part of the thin film transistors are located in the fourth conductive layer.

In some embodiments, orthographic projections of first electrodes of at least part of the light-emitting devices on the base substrate each have a circular contour shape.

In some embodiments, a ratio of a size of the pixel opening of each light-emitting device in a column direction to a size of the pixel opening in a row direction is in a range from 1:1 to 1:3.

In some embodiments, each subpixel includes a plurality of light-emitting devices; and
a distance between light-emitting devices in different subpixels is greater than a distance between the plurality of light-emitting devices in the subpixel including the light-emitting devices.

In some embodiments, the emission layer of each light-emitting device is on a side of the pixel defining layer facing away from the first electrode; and orthographic projections of emission layers of different light-emitting devices on the base substrate are at least partially overlapped with each other.

In some embodiments, orthographic projections of emission layers of at least part of the light-emitting devices on the base substrate each have a circular contour shape; or, orthographic projections of emission layers of at least part of the light-emitting devices on the base substrate each have a symmetrical contour shape enclosed by a plurality of arc-shaped parts and straight sides alternately arranged, and at least two of the arc-shaped parts correspond to a same angle.

In some embodiments, the display substrate further includes a spacer; and the spacer is on a side of the pixel defining layer close to the emission layer.

In some embodiments, for the plurality of pixel units arranged in an array, one spacer is correspondingly provided every 2 to 3 rows of the pixel units and/or every 3 to 5 columns of the pixel units.

In some embodiments, an orthographic projection of each color filter block on the base substrate covers an orthographic projection of a light-emitting device corresponding to the color filter block on the base substrate.

In some embodiments, a distance between a contour edge of the orthographic projection of the color filter block on the base substrate and a contour edge of the orthographic projection of the light-emitting device corresponding to the color filter block on the base substrate is in a range from 1.5 μm to 10.5 μm.

In a second aspect, an embodiment of the present disclosure further provides a display apparatus, including any display substrate as described in the first aspect.

### BRIEF DESCRIPTION OF DRAWINGS

FIG. 1 is a schematic diagram of a diffraction pattern of a conventional real RGB+COE product;

FIG. 2a is a schematic diagram showing main components and structures of a real RGB+COE based display substrate according to an embodiment of the present disclosure;

FIG. 2b is a top view of an exemplary color filter layer according to an embodiment of the present disclosure;

FIG. 3 is a schematic diagram of a pixel arrangement according to an embodiment of the present disclosure;

FIG. 4 is a schematic diagram of a diffraction image of a product based on the pixel arrangement in FIG. 3+COE;

FIG. 5 is a schematic diagram of another pixel arrangement according to an embodiment of the present disclosure;

FIG. 6 is a schematic diagram of another pixel arrangement according to an embodiment of the present disclosure;

FIG. 7 is a diagram showing layers of a light-emitting device according to an embodiment of the present disclosure.

FIG. 8 is a diagram showing layers of another light-emitting device according to an embodiment of the present disclosure.

FIG. 9 is a schematic diagram of another pixel arrangement according to an embodiment of the present disclosure;

FIG. 10 is a schematic diagram of a diffraction image of a product based on the pixel arrangement in FIG. 9+COE;

FIG. 11 is a circuit diagram of a 7TIC pixel drive circuit according to an embodiment of the present disclosure;

FIG. 12 is a diagram showing a structure of a part of an exemplary display substrate according to an embodiment of the present disclosure;

FIG. 13 is a layout diagram of a semiconductor layer according to an embodiment of the present disclosure;

FIG. 14 is a layout diagram of a second conductive layer according to an embodiment of the present disclosure;

FIG. 15 is a layout diagram of a third conductive layer according to an embodiment of the present disclosure;

FIG. 16 is a layout diagram of a fourth conductive layer according to an embodiment of the present disclosure;

FIG. 17 is a layout diagram of a fifth conductive layer according to an embodiment of the present disclosure;

FIGS. 18a to 18d are layout diagrams showing a preparation process of the pixel drive circuit shown in FIGS. 13 to 17;

FIG. 19 is a layout diagram of pixel units according to an embodiment of the present disclosure;

FIG. 20 is a layout diagram of a semiconductor layer according to an embodiment of the present disclosure;

FIG. 21 is a layout diagram of a second conductive layer according to an embodiment of the present disclosure;

FIG. 22 is a layout diagram of a third conductive layer according to an embodiment of the present disclosure;

FIG. 23 is a layout diagram of a fourth conductive layer according to an embodiment of the present disclosure;

FIGS. 24a to 24d are layout diagrams showing a preparation process of the pixel drive circuit shown in FIGS. 20 to 23; and

FIG. 25 is another layout diagram of pixel units according to an embodiment of the present disclosure.

Reference Characters: 1. base substrate; 21. pixel drive circuit; 22. subpixel; 23. color filter layer; 231. red color filter block; 232. green color filter block; 233. blue color filter block; 234. black matrix; TFE. encapsulation layer; Cathod. cathode; R-EL. red emission layer; G-EL. green emission layer; B-EL. blue emission layer; PDL. pixel defining layer; 22-R. red subpixel; 22-G. green subpixel; 22-B. blue subpixel; R. first light-emitting device (red light-emitting device); G1. second light-emitting device (green light-emitting device); G2. fifth light-emitting device (green light-emitting device); B1. third light-emitting device (blue light-emitting device); B2. fourth light-emitting device (blue light-emitting device); L1. first light-emitting device group; L2. second light-emitting device group; B1-Anode. first electrode of blue light-emitting device B1; B2-Anode. first electrode of blue light-emitting device B2; PLN2. second planarization layer; 01. first conductive layer; 3. first connection electrode; 31. first main body part; 32. first branch part; 33. second branch part; 2-1. first pixel unit; 2-2. second pixel unit; t1. first line segment; t2. second line segment; 06. semiconductor layer; 02. second conductive layer; 03. third conductive layer; 04. fourth conductive layer; 05. fifth conductive layer; GI1. first insulation layer; GI2. second insulation layer; ILD. third insulation layer (interlayer insulation layer); T1. first reset transistor; T2. threshold compensation transistor; T3. drive transistor; T4. data write transistor; T5. first emission control transistor; T6. second emission control transistor; T7. second reset transistor; Cst. storage capacitor; CC1. first plate of storage capacitor; CC2. second plate of storage capacitor; T1a. active layer of first reset transistor; T2a. active layer of threshold compensation transistor; T3a. active layer of drive transistor; T4a. active layer of data write transistor; T5a. active layer of first emission control transistor; T6a. active layer of second emission control transistor; T7a. active layer of second reset transistor; T1c. gate of first reset transistor; T2c. gate of threshold compensation transistor; T4c. gate of data write transistor; and T7c. gate of second reset transistor.

### DETAIL DESCRIPTION OF EMBODIMENTS

To clarify the objects, technical solutions and advantages of the embodiments of the present disclosure, the technical solutions in the embodiments of the present disclosure will be clearly and completely described below with reference to the accompanying drawings in the embodiments of the present disclosure. Obviously, the described embodiments are merely some, not all, of the embodiments of the present disclosure. The components in the embodiments of the present disclosure, as generally described and illustrated in the figures herein, could be arranged and designed in a wide variety of different configurations. Therefore, the following detailed description of the embodiments of the present disclosure, provided in the accompanying drawings, is not intended to limit the scope of the present disclosure as claimed, but is merely representative of selected embodiments of the present disclosure. All other embodiments, which can be derived by those skilled in the art from the embodiments of the present disclosure without making any creative effort, shall fall within the protection scope of the present disclosure.

Unless otherwise defined, technical or scientific terms used in the present disclosure are intended to have general meanings as understood by those skilled in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprising” or “including” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, and the like are merely used to indicate a relative positional relationship, and when an absolute position of the described object is changed, the relative positional relationship may be changed accordingly.

Reference to “a plurality of or several” in the present disclosure means two or more. The term “and/or” describes an association relationship of associated objects, which may include three relationships; for example, A and/or B may refer to: A alone, A and B, or B alone. The character “/” generally indicates that the former and latter associated objects are in an “or” relationship.

It should be noted that, in the embodiments of the present disclosure, references to the row direction and the column direction only represent two different directions which are not limited to be perpendicular to each other. In the drawings of the embodiments of the present disclosure, the case where the row direction and the column direction are perpendicular to each other is merely used as an example for illustration, but does not constitute any limitation to the embodiments of the present disclosure.

In addition, references to identical, equal, and the like in the embodiments of the present disclosure do not mean that two objects are exactly the same in size and shape, but are allowed to be approximately the same, approximately equal or the like within a certain error range.

The transistors involved in the embodiments of the present disclosure may be thin film transistors, field effect transistors, or other devices with the same or similar properties, and since the source and the drain of the transistor are symmetrical, the source and the drain are exchangeable. In the embodiments of the present disclosure, for distinguishing purposes, one of the source or the drain of the transistor is referred to as a first electrode, while the other is referred to as a second electrode; and the gate of the transistor is referred to as a control electrode. In addition, transistors may be classified into N-type transistors and P-type transistors according to the characteristics of the transistors. When a P-type transistor is adopted, the first electrode is a drain of the P-type transistor, and the second electrode is a source of the P-type transistor, while for an N type, the contrary is true (the first electrode is a source of the N-type transistor, and the second electrode is a drain of the N-type transistor). The N-type transistor is turned on when a high level signal is applied to the control electrode thereof, and turned off when a low level signal is applied to the control electrode thereof; while the P-type transistor is turned on when a low level signal is applied to the control electrode thereof, and turned off when a high level signal is applied to the control electrode thereof. In the embodiments of the present disclosure, the transistors are exemplarily described as P-type transistors.

In the existing art, among various conventional pixel arrangement modes in a display substrate, the real RGB pixel structure can achieve the best display effect, but may lead to a relatively low resolution of the product due to a large number of pixels and thus limitations of various process factors. Therefore, the real RGB pixel structure is typically applied to display products with relatively low requirements on pixel per inch (PPI), and thus is not suitable for mobile phone products. For example, the real RGB pixel structure is mainly applied to NoteBook computers (NBs), vehicle products, and other display products with relatively low PPI.

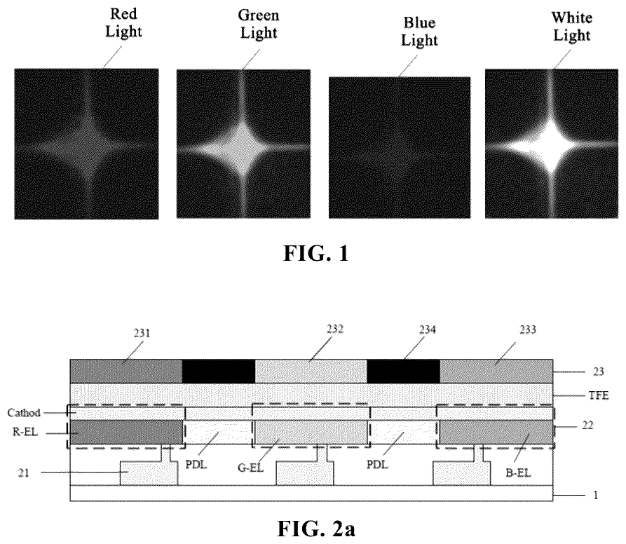

That is, for products with relatively low PPI, such as NB and vehicle products, only the real RGB pixel structure can be adopted for pixel arrangement to meet the image quality requirement. However, a diffraction pattern of a real RGB based COE NB or vehicle product in mass production in the current market typically has a cross structure, as shown in FIG. 1, which is a schematic diagram of the diffraction pattern of a real RGB+COE based vehicle product, and in which color separation can be clearly perceived and thus affects the display quality.

In order to solve the above technical problems, an embodiment of the present disclosure provides a display substrate which can significantly improve color separation generated in a real RGB-based COE product, and improve the display quality of the product.

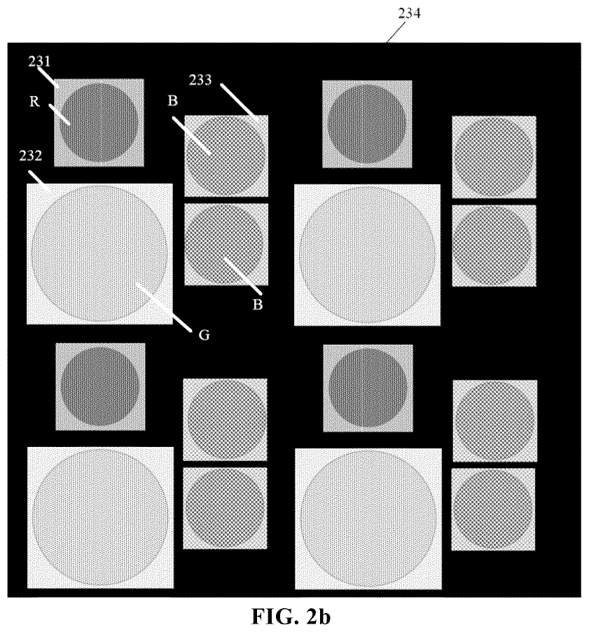

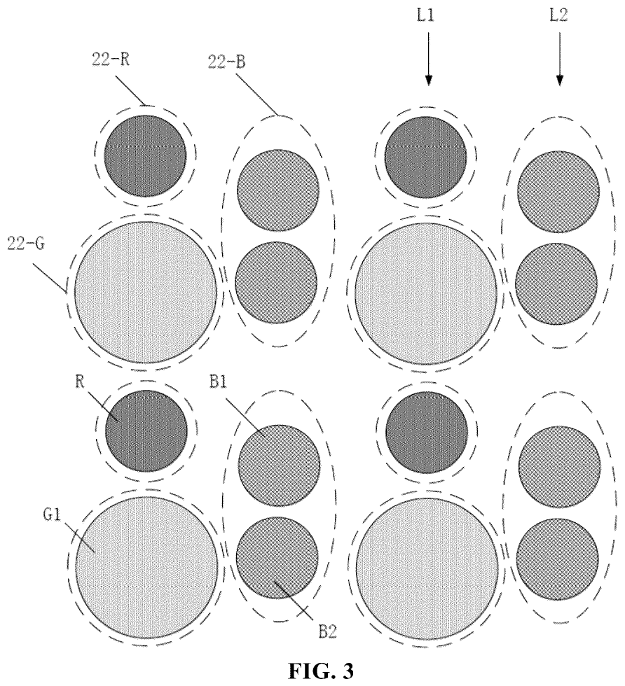

FIG. 2a is a schematic diagram showing main components and structures of a real RGB+COE based display substrate according to an embodiment of the present disclosure. As shown in FIG. 2a, the display substrate includes a base substrate 1, a plurality of pixel units arranged in an array on the base substrate 1, and a color filter layer 23 on a side of the pixel units facing away from the base substrate. An encapsulation layer TFE is disposed on a side of the color filter layer 23 close to subpixels 22.

Each pixel unit includes a plurality of pixel drive circuits 21 and a plurality of light-emitting devices on the base substrate, with each light-emitting device electrically connected to one of the pixel drive circuits 21 to form one subpixel 22. Each light-emitting device is electrically connected to one of the pixel drive circuits 21, and different light-emitting devices may be electrically connected to the same pixel drive circuit 21. For example, one pixel drive circuit 21 may be configured to simultaneously drive a plurality of light-emitting devices in one subpixel. Illustratively, the plurality of subpixels 22 are arranged in a real RGB mode. One pixel drive circuit 21 is configured to drive one subpixel 22. Illustratively, each pixel drive circuit 21 includes at least a plurality of thin film transistors TFT. The subpixel 22 includes a first electrode (e.g., an anode), a second electrode (e.g., a cathode Cathod), and an emission layer (e.g., a red emission layer R-EL, or a green emission layer G-EL, or a blue emission layer B-EL) corresponding to a respective light-emitting device.

Each subpixel 22 includes at least one light-emitting device; and the color filter layer 23 includes a plurality of color filter blocks, with each color filter block disposed corresponding to one of the light-emitting devices. Illustratively, FIG. 2b is a top view of an exemplary color filter layer according to an embodiment of the present disclosure. As shown in FIG. 2b, the color filter layer 23 may be a COE. Specifically, the color filter layer 23 includes a plurality of color filter blocks, such as a red color filter block 231, a green color filter block 232, and a blue color filter block 233. The plurality of color filter blocks are provided in one-to-one correspondence with the light-emitting devices in the plurality of subpixels 22. For example, one red color filter block 231 is provided in correspondence with one red light-emitting device R, one green color filter block 232 is provided in correspondence with one green light-emitting device G, and one blue color filter block 233 is provided in correspondence with one blue light-emitting device B. Illustratively, the red color filter block 231 is configured to filter red light entering the color filter block, so as to transmit red light within the three primary colors for color display. For example, only red light can be transmitted through the red color filter block 231, only green light can be transmitted through the green color filter block 232, only blue light can be transmitted through the blue color filter block 233, so that full-color display is realized. The black matrix 234 is disposed between any adjacent color filter blocks for light shielding, and has a function of absorbing light in all visible wave bands. The black matrix separates the color filter blocks, and prevents color crosstalk between different color filter blocks that may affect the display effect.

The subpixel 22 includes at least one light-emitting device. Orthographic projections of pixel openings of at least part of the light-emitting devices on the base substrate each have a circular contour shape;
and/or, orthographic projections of pixel openings of at least part of the light-emitting devices on the base substrate each have a symmetrical contour shape enclosed by a plurality of arc-shaped parts and straight sides alternately arranged, and at least two of the arc-shaped parts correspond to a same angle, which symmetrical contour shape may include, for example, an elliptical shape, a rounded rectangle shape, a rounded polygonal shape, or the like.

The diffraction image of the real RGB+COE based product in the embodiments of the present disclosure has an approximately circular shape, which can reduce color separation in the product and improve the display effect.

It should be noted that the pixel opening of the light-emitting device may be interpreted as an opening in the pixel defining layer PDL for defining an emission layer of the light-emitting device.

In addition, in consideration of other performances of the product, such as the standby time, the service life and the like, the embodiment of the present disclosure further improves the pixel structure of the display substrate. It should be noted that there are many factors which may affect the standby time and the service life of the product, so the pixel arrangement design has to satisfy many aspects of constraints, and a reasonable pixel arrangement mode is one of the ways to optimize the efficiency and service life of the display product.

Before describing the specific pixel structure of the present disclosure, the plurality of subpixels 22 will be firstly explained. The plurality of subpixels 22 specifically include a red subpixel 22-R, a green subpixel 22-G, and a blue subpixel 22-B. The embodiments of the present disclosure will be described by taking the case where the first subpixel is the red subpixel 22-R, the second subpixel is the green subpixel 22-G, and the third subpixel is the blue subpixel 22-B as an example. The red subpixel 22-R includes at least one red light-emitting device, the green subpixel 22-G includes at least one green light-emitting device, and the blue subpixel 22-B includes at least one blue light-emitting device.

The following embodiments describe different pixel structures in detail.

FIG. 3 is a schematic diagram of a pixel arrangement according to an embodiment of the present disclosure. In some embodiments, as shown in FIG. 3, the plurality of subpixels 22 include a red subpixel 22-R, a green subpixel 22-G, and a blue subpixel 22-B; the red subpixel 22-R includes a red light-emitting device R; the green subpixel 22-G includes a green light-emitting device G1; and the blue subpixel 22-B includes blue light-emitting devices B1 and B2. For the plurality of pixel units arranged in an array, red light-emitting devices R and green light-emitting devices G1 are alternately arranged in the column direction to form multiple columns of first light-emitting device groups L1; and blue light-emitting devices B1 and blue light-emitting devices B2 are alternately arranged in the column direction to form multiple columns of second light-emitting device groups L2.

Illustratively, in the pixel arrangement mode shown in FIG. 3, each pixel unit includes four emission regions, and may use three pixel drive circuits 21, that is, a first pixel drive circuit 21 for the red light-emitting device R, a second pixel drive circuit 21 for the green light-emitting device G1, and a third pixel drive circuit 21 shared by the blue light-emitting devices B1 and B2, where the two display regions of the blue light-emitting devices are simultaneously lightened upon lighting.

Further, orthographic projections of pixel openings of the red light-emitting device R, the green light-emitting device G1, the blue light-emitting devices B1 and B2 on the base substrate 1 each have a circular contour shape.

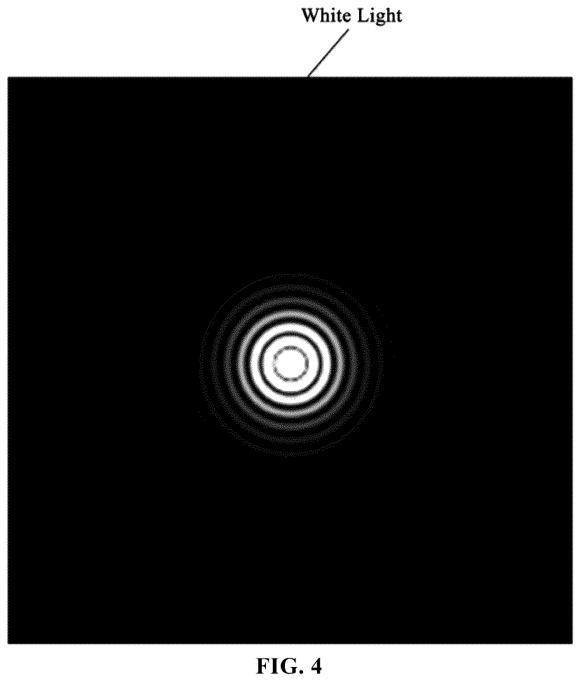

FIG. 4 is a schematic diagram of a diffraction image of a product based on the pixel arrangement in FIG. 3+COE. As shown in FIG. 4, in the embodiment of the present disclosure, the pixel arrangement mode in FIG. 3 is adopted and the pixel opening of the light-emitting device is set to be circular, so that the diffraction pattern is rounded, that is, color separation is improved; meanwhile, the pixel opening of each subpixel 22 is maximized, which can increase the brightness, reduce the risk of screen burning due to long time operation, and thereby prolong the service life of the product.

In some embodiments, for one of the pixel units, the red subpixel 22-R has an aperture ratio A, the green subpixel 22-G has an aperture ratio B, and the blue subpixel 22-B has an aperture ratio C; where A:B:C is one of 1:(1.7 to 2.2):(1.4 to 2).

It should be noted that the aperture ratio of the subpixel 22 is a ratio of a sum of areas of the pixel openings of the light-emitting devices in the subpixel to a total area occupied by the pixel unit. In addition to an area of the pixel opening defined by the pixel defining layer PDL, the total area occupied by the pixel unit further includes a projected area of a retaining wall between adjacent light-emitting devices.

For example, the aperture ratio A of the red subpixel 22-R is a ratio of a sum of areas of the pixel openings of the light-emitting devices in the red subpixel 22-R to a total area occupied by the pixel unit. For example, the aperture ratio B of the green subpixel 22-G is a ratio of a sum of areas of the pixel openings of the light-emitting devices in the green subpixel 22-G to a total area occupied by the pixel unit. For example, the aperture ratio C of the blue subpixel 22-B is a ratio of a sum of areas of the pixel openings of the light-emitting devices in the blue subpixel 22-B to a total area occupied by the pixel unit. The ratio A:B:C represents a ratio of aperture ratios of the red subpixel 22-R, the green subpixel 22-G, and the blue subpixel 22-B.

Illustratively, the ratio of aperture ratios of the red subpixel 22-R, the green subpixel 22-G, and the blue subpixel 22-B is one of 1:(1.7 to 2.2):(1.4 to 2).

Taking the case where the red subpixel 22-R includes a red light-emitting device R, the green subpixel 22-G includes a green light-emitting device G1, and the blue subpixel 22-B includes blue light-emitting devices B1 and B2 as an example, the ratio of aperture ratios of the red subpixel 22-R (red light-emitting device R), the green subpixel 22-G (green light-emitting device G1), and the blue subpixel 22-B (blue light-emitting devices B1+B2) is one of 1:1.7:1.4, 1:2:1.8, or 1:2.2:2.

By reasonably optimizing the ratio of aperture ratios of subpixels 22, this embodiment can maximize the pixel opening of each subpixel 22, increase the brightness, reduce the risk of screen burning due to long time operation, and thereby prolong the service life of the product.

Apparently, the ratio of aperture ratios may also be adjusted according to the actual applications of the product, which is not specifically limited in the embodiments of the present disclosure.

In some embodiments, each pixel unit has an aperture ratio in a range from 10% to 55%. It should be noted that the aperture ratio of the pixel unit is a ratio of a sum of areas of the pixel openings of the light-emitting devices in the pixel unit to a total area occupied by the pixel unit. In addition to an area of the pixel opening defined by the pixel defining layer PDL, the total area occupied by the pixel unit further includes a projected area of a retaining wall between adjacent light-emitting devices.

Illustratively, the aperture ratios of different subpixels in the same pixel unit may be determined according to an actual aperture ratio range of the pixel unit and the ratio of aperture ratios of the subpixels. For example, if the ratio of aperture ratios of the red subpixel 22-R, the green subpixel 22-G, and the blue subpixel 22-B is 1:1.7:1.4, and the aperture ratio of the pixel unit is 41%, then the aperture ratio of the red subpixel 22-R is 10%, the aperture ratio of the green subpixel 22-G is 17%, and the aperture ratio of the blue subpixel 22-B is 14%.

In some embodiments, the blue light-emitting device B1 has the same aperture ratio as the blue light-emitting device B2. The aperture ratio of the blue light-emitting device B1 is a ratio of an area of the pixel opening of the blue light-emitting device B1 to an entire area occupied by one pixel unit. The aperture ratio of the blue light-emitting device B2 is a ratio of an area of the pixel opening of the blue light-emitting device B2 to an entire area occupied by one pixel unit. For example, if the aperture ratio of the blue subpixel 22-B is 14%, then the blue light-emitting devices B1 and B2 each have an aperture ratio of 7%.

By reasonably optimizing the aperture ratio of each subpixel 22, this embodiment can maximize the pixel opening of each subpixel 22, increase the brightness, reduce the risk of screen burning due to long time operation, and thereby prolong the service life of the product.

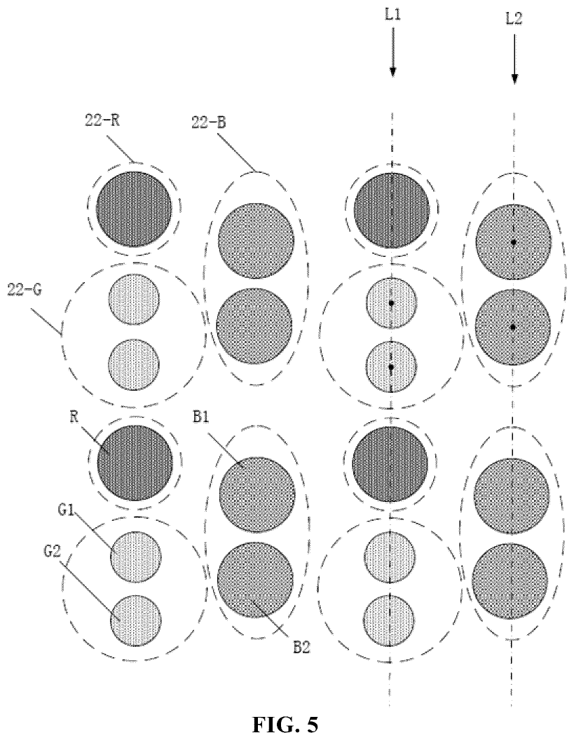

FIG. 5 is a schematic diagram of another pixel arrangement according to an embodiment of the present disclosure, and FIG. 6 is a schematic diagram of another pixel arrangement according to an embodiment of the present disclosure. In some embodiments, as shown in FIGS. 5 and 6, the plurality of subpixels 22 include a red subpixel 22-R, a green subpixel 22-G, and a blue subpixel 22-B; the red subpixel 22-R includes a red light-emitting device R; the green subpixel 22-G includes green light-emitting devices G1 and G2; and the blue subpixel 22-B includes blue light-emitting devices B1 and B2. For the plurality of pixel units arranged in an array, red light-emitting devices R and green subpixels 22-G are alternately arranged in the column direction to form multiple columns of first light-emitting device groups L1; and blue light-emitting devices B1 and blue light-emitting devices B2 are alternately arranged in the column direction to form multiple columns of second light-emitting device groups L2.

An extension line of a connection line between center points of the green light-emitting devices G1 and G2 forms an angle in a range of 0° to 90° with an extension line of a connection line between center points of the blue light-emitting devices B1 and B2.

Illustratively, each pixel unit includes five emission regions, and may use three pixel drive circuits 21, that is, a first pixel drive circuit 21 for the red light-emitting device R, a second pixel drive circuit 21 shared by the green light-emitting devices G1 and G2, and a third pixel drive circuit 21 shared by the blue light-emitting devices B1 and B2, where the two display regions of the green light-emitting devices are simultaneously lightened upon lighting, and the two display regions of the blue light-emitting devices are simultaneously lightened upon lighting.

Illustratively, as shown in FIG. 5, the extension line of the connection line between center points of the green light-emitting devices G1 and G2 forms an angle in a range of 0° with the extension line of the connection line between center points of the blue light-emitting devices B1 and B2. In other words, the extension line of the connection line between center points of the green light-emitting devices G1 and G2 is parallel to the extension line of the connection line between center points of the blue light-emitting devices B1 and B2.

Illustratively, as shown in FIG. 6, the extension line of the connection line between center points of the green light-emitting devices G1 and G2 forms an angle in a range of 45° with the extension line of the connection line between center points of the blue light-emitting devices B1 and B2.

Further, orthographic projections of pixel openings of the red light-emitting device R, the green light-emitting device G1, the blue light-emitting device B1, the blue light-emitting device B2, and the green light-emitting device G2 on the base substrate 1 each have a circular contour shape.

In the embodiments of the present disclosure, the pixel arrangement mode in FIG. 5 or 6 is adopted and the pixel opening of the light-emitting device is set to be circular, so that the diffraction pattern is rounded, that is, color separation is improved; meanwhile, the pixel opening of each subpixel 22 is maximized, which can increase the brightness, reduce the risk of screen burning due to long time operation, and thereby prolong the service life of the product. In addition, for the green subpixel 22-G and the blue subpixel 22-B, the green subpixel 22-G includes two green light-emitting devices, and the blue subpixel 22-B includes two blue light-emitting devices, so that the aperture ratios of the green and blue light-emitting devices are increased in this embodiment, which can increase the brightness, reduce the risk of screen burning due to long time operation, and thereby prolong the service life of the product.

Taking the case where the red subpixel 22-R includes the red light-emitting device R, the green subpixel 22-G includes the green light-emitting devices G1 and G2, and the blue subpixel 22-B includes the blue light-emitting devices B1 and B2 as an example, the ratio of aperture ratios of the red subpixel 22-R, the green subpixel 22-G, and the blue subpixel 22-B is one of 1:(1.7 to 2.2):(1.4 to 2). Illustratively, the ratio of aperture ratios of the red subpixel 22-R, the green subpixel 22-G, and the blue subpixel 22-B is one of 1:1.7:1.4, 1:2:1.8 or 1:2.2:2.

By reasonably optimizing the ratio of aperture ratio of each subpixel 22, this embodiment can maximize the pixel opening of each subpixel 22, increase the brightness, reduce the risk of screen burning due to long time operation, and thereby prolong the service life of the product.

In some embodiments, each pixel unit has an aperture ratio in a range from 10% to 55%.

Illustratively, the aperture ratios of different subpixels in the same pixel unit may be determined according to an actual aperture ratio range of the pixel unit and the ratio of aperture ratios of the subpixels. For example, if the ratio of aperture ratios of the red subpixel 22-R, the green subpixel 22-G, and the blue subpixel 22-B is 1:2:1.8, and the aperture ratio of the pixel unit is 48%, then the aperture ratio of the red subpixel 22-R is 10%, the aperture ratio of the green subpixel 22-G is 20%, and the aperture ratio of the blue subpixel 22-B is 18%.

In some embodiments, the green light-emitting device G1 has the same aperture ratio as the green light-emitting device G2. The aperture ratio of the green light-emitting device G1 is a ratio of an area of the pixel opening of the green light-emitting device G1 to an entire area occupied by one pixel unit. The aperture ratio of the green light-emitting device G2 is a ratio of an area of the pixel opening of the green light-emitting device G2 to an entire area occupied by one pixel unit.

For example, if the aperture ratio of the green subpixel 22-G is 18%, then the green light-emitting devices G1 and G2 each have an aperture ratio of 9%.

By reasonably optimizing the aperture ratio of each subpixel 22, this embodiment can maximize the pixel opening of each subpixel 22, increase the brightness, reduce the risk of screen burning due to long time operation, and thereby prolong the service life of the product.

In the case where the subpixel 22 includes a plurality of light-emitting devices, one pixel drive circuit 21 is configured to drive a plurality of light-emitting devices in one subpixel 22. Specifically, anodes of the light-emitting devices in one subpixel 22 are each electrically connected to the same pixel drive circuit 21.

In some embodiments, for the pixel arrangement shown in FIG. 3, 5 or 6, the display substrate further includes a first conductive layer 01 on a side of the pixel drive circuits 21 facing away from the base substrate 1, and a pixel defining layer PDL on a side of the first conductive layer 01 facing away from the base substrate 1; and the light-emitting device includes a pixel opening penetrating through the pixel defining layer PDL, and a first electrode formed on a side of the pixel defining layer PDL close to the pixel drive circuit 21, and an emission layer and a second electrode at least in the pixel opening. The first conductive layer 01 includes the first electrode of each light-emitting device; and for the blue subpixel 22-B, a first electrode B1-Anode of the blue light-emitting device B1 is electrically connected to a first electrode B2-Anode of the blue light-emitting device B2.

Illustratively, the first electrode B1-Anode of the blue light-emitting device B1 may be electrically connected to the first electrode B2-Anode of the blue light-emitting device B2 directly, or indirectly via a connection electrode, which may be specifically set according to the actual pixel arrangement and wiring layout of the light-emitting devices.

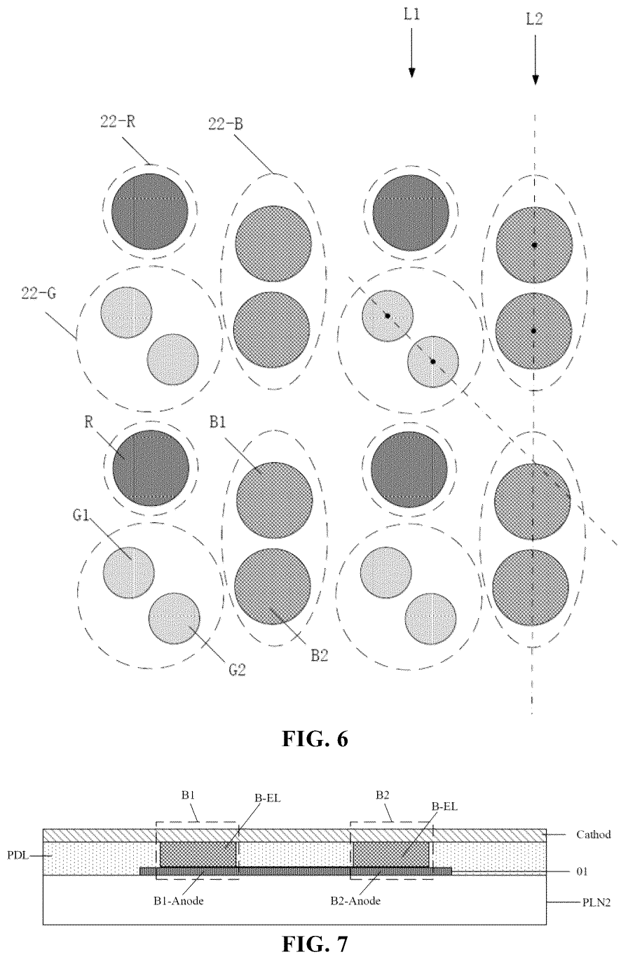

FIG. 7 is a diagram showing layers of a light-emitting device according to an embodiment of the present disclosure. For example, as shown in FIG. 7, the first electrode B1-Anode of the blue light-emitting device B1 and the first electrode B2-Anode of the blue light-emitting device B2 are connected into an integral structure, and disposed on a side of the second planarization layer PLN2 close to the pixel defining layer PDL. The first electrode B1-Anode of the blue light-emitting device B1 and the first electrode B2-Anode of the blue light-emitting device B2 are disposed in the same layer, i.e., in the first conductive layer 01, and may be formed through one patterning process, in which case a hollowed-out portion of the mask corresponding to the first electrodes of the two blue light-emitting devices is a closed pattern. Here, although the first electrode B1-Anode of the blue light-emitting device B1 and the first electrode B2-Anode of the blue light-emitting device B2 are connected into an integral structure, a retaining wall of the pixel defining layer PDL is disposed above the connection between the first electrode B1-Anode of the blue light-emitting device B1 and the first electrode B2-Anode of the blue light-emitting device B2, to define the blue emission layers B-EL of different blue light-emitting devices.

For example, FIG. 8 is a diagram showing layers of another light-emitting device according to an embodiment of the present disclosure. As shown in FIG. 8, the first electrode B1-Anode of the blue light-emitting device B1 is disconnected from the first electrode B2-Anode of the blue light-emitting device B2. For the blue subpixel 22-B, the pixel drive circuit 21 includes a drive transistor and a first connection electrode 3 electrically connected to the drive transistor; the first connection electrode 3 includes a first main body part 31 (referring to FIG. 12), and a first branch part 32 and a second branch part 33 each electrically connected to the first main body part 31; and the first branch part 32 is electrically connected to the first electrode B1-Anode of the blue light-emitting device B1, while the second branches part 33 is electrically connected to the first electrode B2-Anode of the blue light-emitting device B2. The first electrode B1-Anode of the blue light-emitting device B1 and the first electrode B2-Anode of the blue light-emitting device B2 are disposed in the same layer, i.e., in the first conductive layer 01, and may be formed through one patterning process, in which case a hollowed-out portion of the mask corresponding to the first electrodes of the two blue light-emitting devices includes two closed patterns. In addition, a retaining wall of the pixel defining layer PDL is disposed at the disconnection between the first electrode B1-Anode of the blue light-emitting device B1 and the first electrode B2-Anode of the blue light-emitting device B2, to define the blue emission layers B-EL of different blue light-emitting devices.

In some embodiments and in combination with the above embodiments, for the pixel arrangement shown in FIG. 5 or 6, in addition to that for the blue subpixel 22-B, the first electrode B1-Anode of the blue light-emitting device B1 is electrically connected to the first electrode B2-Anode of the blue light-emitting device B2, for the green subpixel 22-G, a first electrode of green light-emitting device G1 is electrically connected to a first electrode of the green light-emitting device G2.

Illustratively, the first electrode of green light-emitting device G1 may be electrically connected to the first electrode of the green light-emitting device G2 directly, or indirectly via a connection electrode, which may be specifically set according to the actual pixel arrangement and wiring layout of the light-emitting devices.

The first electrode of the green light-emitting device G1 and the first electrode of the green light-emitting device G2 are connected into an integral structure, similar to the first electrode B1-Anode and the first electrode B2-Anode connected into an integral structure in FIG. 7. The first electrode of the green light-emitting device G1 and the first electrode of the green light-emitting device G2 are disposed in the same layer, i.e., in the first conductive layer 01, and may be formed through one patterning process, in which case a hollowed-out portion of the mask corresponding to the first electrodes of the two green light-emitting devices is a closed pattern. Here, although the first electrode of the green light-emitting device G1 and the first electrode of the green light-emitting device G2 are connected into an integral structure, a retaining wall of the pixel defining layer PDL is disposed above the connection between the first electrode of the green light-emitting device G1 and the first electrode of the green light-emitting device G2, to define the emission layers of different green light-emitting devices.

The first electrode of the green light-emitting device G1 is disconnected from the first electrode of the green light-emitting device G2, similar to the first electrode B1-Anode disconnected from first electrode B2-Anode shown in FIG. 8. For the green subpixel 22-G, the pixel drive circuit 21 includes a drive transistor and a second connection electrode electrically connected to the drive transistor. The second connection electrode includes a second main body part, and a third branch part and a fourth branch part each electrically connected to the second main body part; and the third branch part is electrically connected to the first electrode of the green light-emitting device G1, while the fourth branch part is electrically connected to the first electrode of the green light-emitting device G2. The first electrode of the green light-emitting device G1 and the first electrode of the green light-emitting device G2 are disposed in the same layer, i.e., in the first conductive layer 01, and may be formed through one patterning process, in which case a hollowed-out portion of the mask corresponding to the first electrodes of the two green light-emitting devices includes two closed patterns. In addition, a retaining wall of the pixel defining layer PDL is disposed at the disconnection between the first electrode of the green light-emitting device G1 and the first electrode of the green light-emitting device G2, to define the emission layers of different green light-emitting devices.

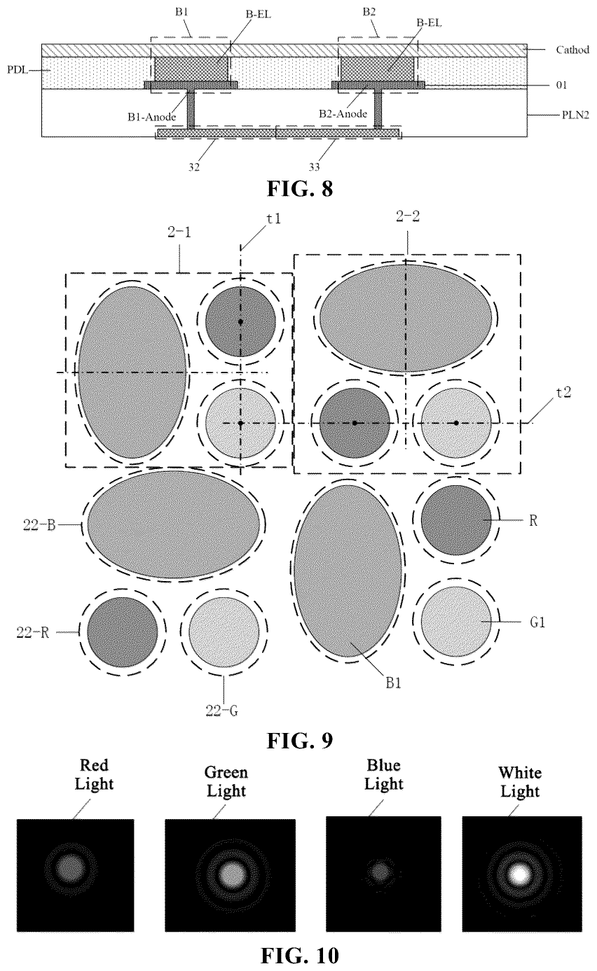

FIG. 9 is a schematic diagram of another pixel arrangement according to an embodiment of the present disclosure. In some embodiments, as shown in FIG. 9, the plurality of pixel units include a first pixel unit 2-1 and a second pixel unit 2-2, and first pixel units 2-1 and second pixel units 2-2 are alternately arranged in each of a row direction and a column direction. Each of the first pixel unit 2-1 and the second pixel unit 2-2 includes a red subpixel 22-R, a green subpixel 22-G, and a blue subpixel 22-B. The red subpixel 22-R includes a red light-emitting device R, the green subpixel 22-G includes a green light-emitting device G1, and the blue subpixel 22-B includes a blue light-emitting device B1. For the first pixel unit 2-1, the red light-emitting device R and the green light-emitting device G1 are located in the same column, which is a column adjacent to a column where the blue light-emitting device B1 is located. For the second pixel unit 2-2, the red light-emitting device R and the green light-emitting device G1 are located in a same row, which is a row adjacent to a row where the blue light-emitting device B1 is located. A connection line between center points of the red light-emitting device R and the green light-emitting device G1 in the first pixel unit 2-1 is a first line segment t1, while a connection line between center points of the red light-emitting device R and the green light-emitting device G1 in the second pixel unit 2-2 is a second line segment t2. An extending direction of the first line segment t1 is perpendicular to an extending direction of the second line segment t2.

Illustratively, in the pixel arrangement mode shown in FIG. 9, each pixel unit includes three emission regions, and may use three pixel drive circuits 21, i.e., a first pixel drive circuit 21 for the red light-emitting device R, a second pixel drive circuit 21 for the green light-emitting device G1, and a third pixel drive circuit 21 for the blue light-emitting device B1.

Further, orthographic projections of pixel openings of the red light-emitting device R and the green light-emitting device G1 on the base substrate 1 each have a circular contour shape; and an orthographic projection of a pixel opening of the blue light-emitting device B1 on the base substrate 1 has an elliptical contour shape.

FIG. 10 is a schematic diagram of a diffraction image of a product based on the pixel arrangement in FIG. 9+COE. As shown in FIG. 10, in this embodiment, the pixel arrangement mode in FIG. 9 is adopted and the pixel openings of the red light-emitting device R and the green light-emitting device G1 are set to be circular, while the pixel opening of the blue light-emitting device B1 is set to be elliptical, which also achieves rounding of the diffraction pattern, that is, improves color separation; meanwhile, the pixel opening of each subpixel 22 is maximized, which can increase the brightness, reduce the risk of screen burning due to long time operation, and thereby prolong the service life of the product.

Further, taking the case where the orthographic projections of pixel openings of the red light-emitting device R and the green light-emitting device G1 on the base substrate 1 each have a circular contour shape, and the orthographic projection of a pixel opening of the blue light-emitting device B1 on the base substrate 1 has an elliptical contour shape as an example, as shown in FIG. 9, for the first pixel unit 2-1, an extending direction of the first line segment t1 is perpendicular to an extending direction of a minor axis corresponding to the contour of the pixel opening of the blue light-emitting device B1; and for the second pixel unit 2-2, an extending direction of the second line segment t2 is perpendicular to the extending direction of a minor axis corresponding to the contour of the pixel opening of the blue light-emitting device B1.

By means of the orthogonal design of adjacent pixel units, this embodiment can facilitate uniform distribution of the light-emitting devices, and, in conjunction with the design that maximizes the pixel opening, can improve color cast of the product and further improve color separation.

In some embodiments, for one of the pixel units, the ratio of aperture ratios of the red subpixel 22-R, the green subpixel 22-G, and the blue subpixel 22-B is one of 1:(1.7 to 2.2):(1.4 to 2).

Taking the case where the red subpixel 22-R includes a red light-emitting device R, the green subpixel 22-G includes a green light-emitting device G1, and the blue subpixel 22-B includes a blue light-emitting device B1; the orthographic projections of pixel openings of the red light-emitting device R and the green light-emitting device G1 on the base substrate 1 each have a circular contour shape; and the orthographic projection of a pixel opening of the blue light-emitting device B1 on the base substrate 1 has an elliptical contour shape as an example, the ratio of aperture ratios of the red subpixel 22-R (red light-emitting device R), the green subpixel 22-G (green light-emitting device G1), and the blue subpixel 22-B (blue light-emitting device B1) is one of 1:1.7:1.4, 1:2:1.8 or 1:2.2:2.

By reasonably optimizing the ratio of aperture ratio of each subpixel 22, this embodiment can maximize the pixel opening of each subpixel 22, increase the brightness, reduce the risk of screen burning due to long time operation, and thereby prolong the service life of the product.

Apparently, the ratio of aperture ratios may also be adjusted according to the actual applications of the product, which is not specifically limited in the embodiments of the present disclosure.

In some embodiments, each pixel unit has an aperture ratio in a range from 10% to 55%.

By reasonably optimizing the aperture ratio of each subpixel 22, this embodiment can maximize the pixel opening of each subpixel 22, increase the brightness, reduce the risk of screen burning due to long time operation, and thereby prolong the service life of the product.

In some embodiments, each subpixel 22 in the embodiments of the present disclosure may be driven by the pixel drive circuit 21 of the same structure.

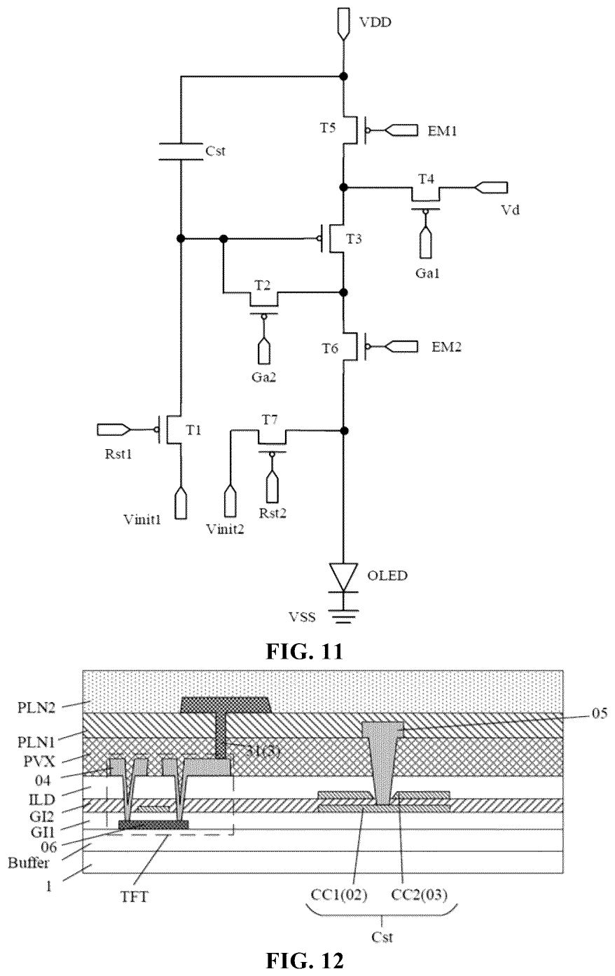

It should be noted that in the case where the pixel drive circuit 21 provided in the embodiments of the present disclosure may adopt the 7T1C (7 transistors and 1 capacitor) shown in FIG. 11. FIG. 11 is merely for exemplary purposes, and does not configure any limitation to the technical solution of the present disclosure. The pixel drive circuit 21 may also adopt a structure of other numbers of transistors, such as a 7T2C structure, a 6T1C structure, a 6T2C structure, or a 9T2C structure, which is not limited in the embodiments of the present disclosure.

FIG. 12 is a diagram showing a structure of a part of an exemplary display substrate according to an embodiment of the present disclosure. As shown in FIG. 12, the display substrate further includes a semiconductor layer 06 on the base substrate 1, a second conductive layer 02 on a side of the semiconductor layer 06 facing away from the base substrate 1, a third conductive layer 03 on a side of the second conductive layer 02 facing away from the base substrate 1, and a fourth conductive layer 04 on a side of the second conductive layer 02 close to the third conductive layer 03. Each pixel drive circuit 21 includes at least a plurality of thin film transistors TFT and a storage capacitor Cst; an active layer of each thin film transistor TFT is located in the semiconductor layer 06; gates of at least part of the thin film transistors TFT and a first plate of the storage capacitor Cst are located in the second conductive layer 02; a second plate of the storage capacitor Cst is located in the third conductive layer 03; and control signal lines of at least part of the thin film transistors TFT are located in the fourth conductive layer 04.

As shown in FIG. 12, a buffer layer is disposed on the base substrate 1; a semiconductor layer 06 is disposed on a side of the buffer layer facing away from the base substrate 1; a first insulation layer (i.e., a gate insulation layer) is disposed on a side of the semiconductor layer 06 facing away from the buffer layer; the second conductive layer 02 is disposed on a side of the first insulation layer facing away from the semiconductor layer 06; a second insulation layer is disposed on a side of the second conductive layer 02 facing away from the first insulation layer; the third conductive layer 03 is disposed on a side of the second insulation layer facing away from the second insulation layer; a third insulation layer is disposed on a side of the third conductive layer 03 facing away from the second insulation layer; the fourth conductive layer 04 is disposed on a side of the third insulation layer facing away from the third conductive layer 03; a passivation layer PVX is disposed on a side of the fourth conductive layer 04 facing away from the third insulation layer; a first planarization layer PLN1 is disposed on a side of the passivation layer PVX facing away from the fourth conductive layer 04; a connection electrode (e.g., a first connection electrode 3 and/or a second connection electrode) is disposed on a side of the first planarization layer PLN1 facing away from the passivation layer PVX; and a second planarization layer PLN2 is disposed on a side of the connection electrode facing away from the first planarization layer PLN1.

Taking a 7T1C pixel drive circuit 21 as an example, the pixel drive circuit 21 includes seven thin film transistors TFT and one storage capacitor Cst, which, as shown in FIG. 11, specifically include a first reset transistor T1, a threshold compensation transistor T2, a drive transistor T3, a data write transistor T4, a first emission control transistor T5, a second emission control transistor T6, a second reset transistor T7, a storage capacitor Cst, a first plate CC1, and a second plate CC2.

A source of the data write transistor T4 is electrically connected to a source of the drive transistor T3, a drain of the data write transistor T4 is configured to be electrically connected to a data line Vd to receive a data signal, and a gate T4c of the data write transistor T4 is configured to be electrically connected to a first scanning signal line Ga1 to receive a scanning signal. A first plate CC1 of the storage capacitor Cst is electrically connected to a first power voltage terminal VDD, and a second plate CC2 of the storage capacitor Cst is electrically connected to a gate of the drive transistor T3. A source of the threshold compensation transistor T2 is electrically connected to a drain of the drive transistor T3, a drain of the threshold compensation transistor T2 is electrically connected to the gate of the drive transistor T3, and a gate T2c of the threshold compensation transistor T2 is configured to be electrically connected to a second scanning signal line Ga2 to receive a compensation control signal. A source of the first reset transistor T1 is configured to be electrically connected to a first reset power terminal Vinit1 to receive a first reset signal, a drain of the first reset transistor T1 is electrically connected to the gate of the drive transistor T3, and a gate T1c of the first reset transistor T1 is configured to be electrically connected to a first reset control signal line Reset1 to receive a first reset control sub-signal. A source of the second reset transistor T7 is configured to be electrically connected to a second reset power terminal Vinit2 to receive a second reset signal, a drain of the second reset transistor T7 is electrically connected to a first electrode the light-emitting device OLED, and a gate T7c of the second reset transistor T7 is configured to be electrically connected to a second reset control signal line Reset2 to receive a second reset control sub-signal. A source of the first emission control transistor T5 is electrically connected to the first power voltage terminal VDD, a drain of the first emission control transistor T5 is electrically connected to the source of the drive transistor T3, and a gate of the first emission control transistor T5 is configured to be electrically connected to a first emission control signal line EM1 to receive a first emission control signal. A source of the second emission control transistor T6 is electrically connected to the drain of the drive transistor T3, a drain of the second emission control transistor T6 is electrically connected to a first electrode D1 the light-emitting device OLED, and a gate of the second emission control transistor T6 is configured to be electrically connected to a second emission control signal line EM2 to receive a second emission control signal. A second electrode the light-emitting device OLED is electrically connected to a second power voltage terminal VSS.

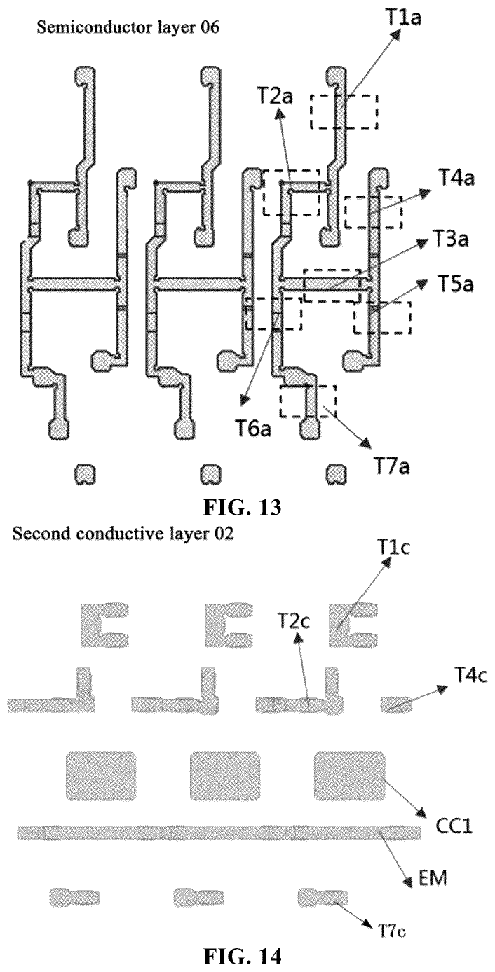

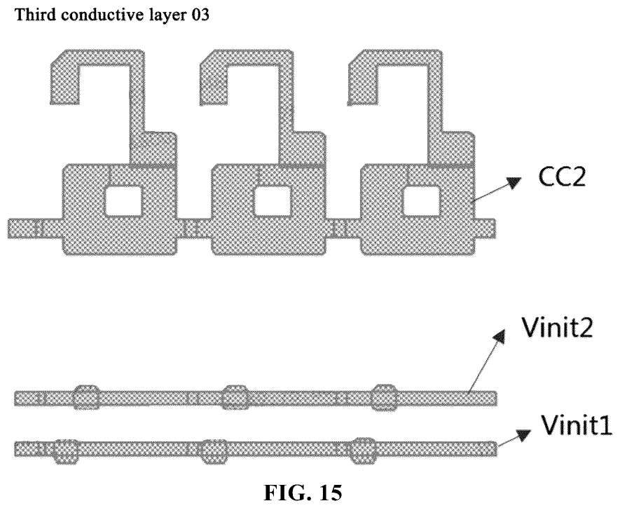

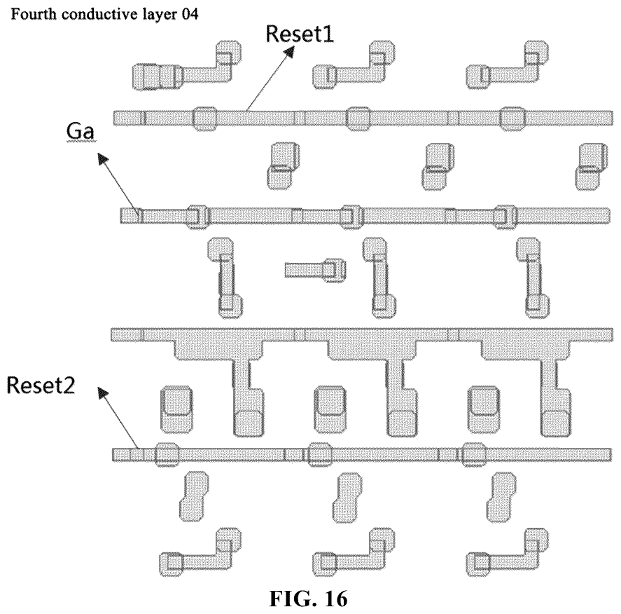

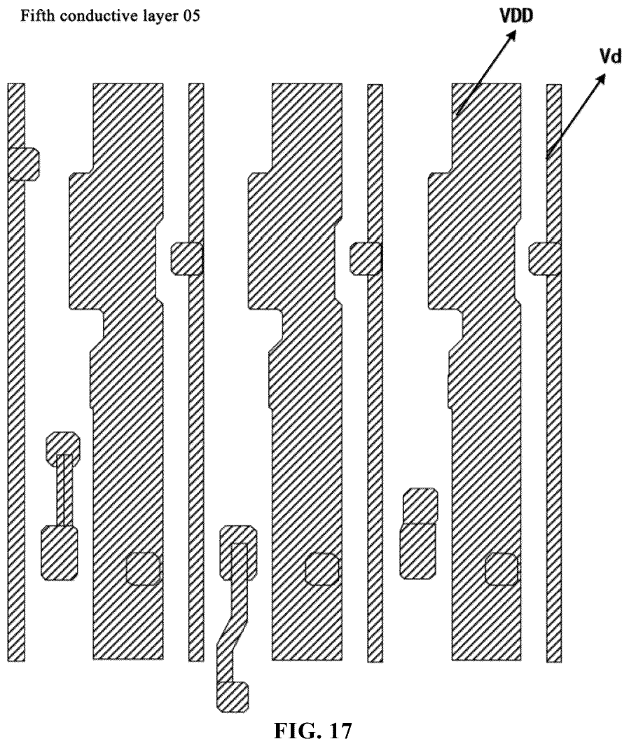

In one possible implementation, taking a 7T1C pixel drive circuit 21 as an example, FIG. 13 is a layout diagram of a semiconductor layer 06 according to an embodiment of the present disclosure, FIG. 14 is a layout diagram of a second conductive layer 02 according to an embodiment of the present disclosure, FIG. 15 is a layout diagram of a third conductive layer 03 according to an embodiment of the present disclosure, FIG. 16 is a layout diagram of a fourth conductive layer 04 according to an embodiment of the present disclosure, and FIG. 17 is a layout diagram of a fifth conductive layer 05 according to an embodiment of the present disclosure.

As shown in FIG. 13, an active layer T1a of the first reset transistor T1, an active layer T2a of the threshold compensation transistor T2, an active layer T3a of the drive transistor T3, an active layer T4a of the data write transistor T4, an active layer T5a of the first emission control transistor T5, an active layer T6a of the second emission control transistor T6, and an active layer T7a of the second reset transistor T7 are all located in the semiconductor layer 06.

As shown in FIG. 14, a gate T1c of the first reset transistor T1, a gate T2c of the threshold compensation transistor T2, a gate T4c of the data write transistor T4, a gate T7c of the second reset transistor T7, a first plate CC1 of the storage capacitor Cst, and a gate of the first emission control transistor T5, a gate of the second emission control transistor T6, a first emission control signal line EM1, and a second emission control signal line EM2 are all located in the second conductive layer 02. The gate of the first emission control transistor T5, the gate of the second emission control transistor T6, the first emission control signal line EM1, and the second emission control signal line EM2 form an integral structure (EM in FIG. 14).

As shown in FIG. 15, a gate of the drive transistor T3, a second plate CC2 of the storage capacitor Cst, a signal line drawn from the first reset power terminal Vinit1 and electrically connected to the source of the first reset transistor T1, and a signal line drawn from the second reset power terminal Vinit2 and electrically connected to the source of the second reset transistor T7 are all located in the third conductive layer 03. The gate of the drive transistor T3 and the second plate CC2 of the storage capacitor Cst form an integral structure (CC2 in FIG. 15).

As shown in FIG. 16, the first scanning signal line Ga1 (the control signal line of the data write transistor T4), the second scanning signal line Ga2 (the control signal line of the threshold compensation transistor T2), the first reset control signal line Reset1 (the control signal line of the first reset transistor T1), and the second reset control signal line Reset2 (the control signal line of the second reset transistor T7), are all located in the fourth conductive layer 04. The first scanning signal line Ga1 and the second scanning signal line Ga2 are connected into an integral structure (Ga in FIG. 16).

As shown in FIG. 17, a data line Vd is located in the fifth conductive layer 05, and a signal line drawn from the first power voltage terminal VDD and electrically connected to the first plate CC1 of the storage capacitor Cst and a source of the first emission control transistor T5, is also located in the fifth conductive layer 05.

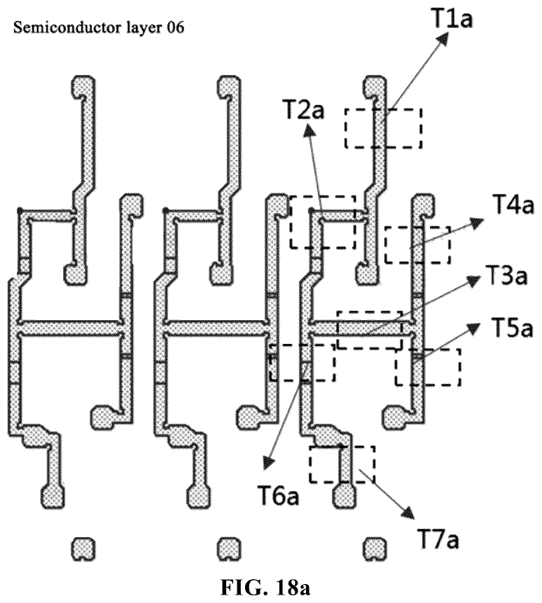

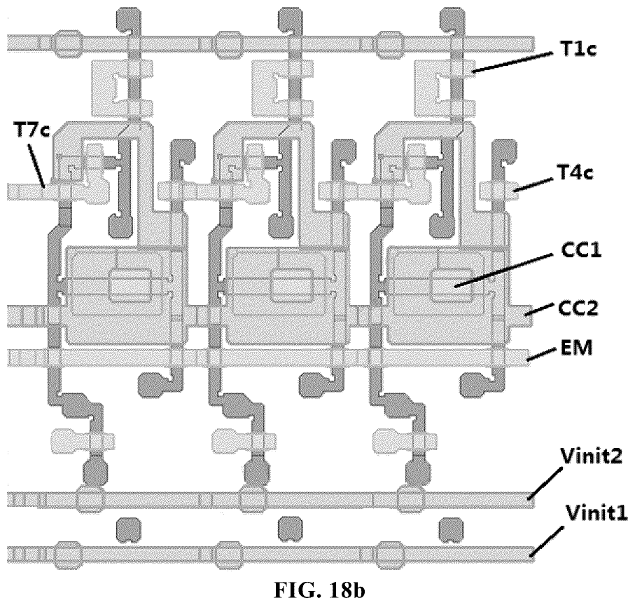

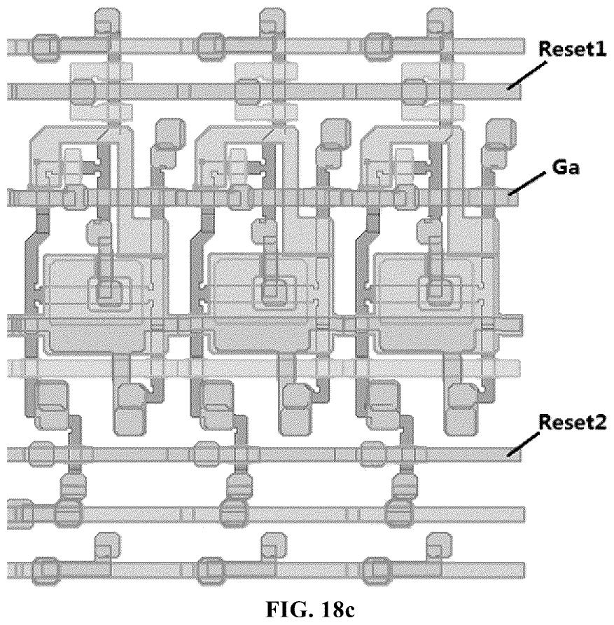

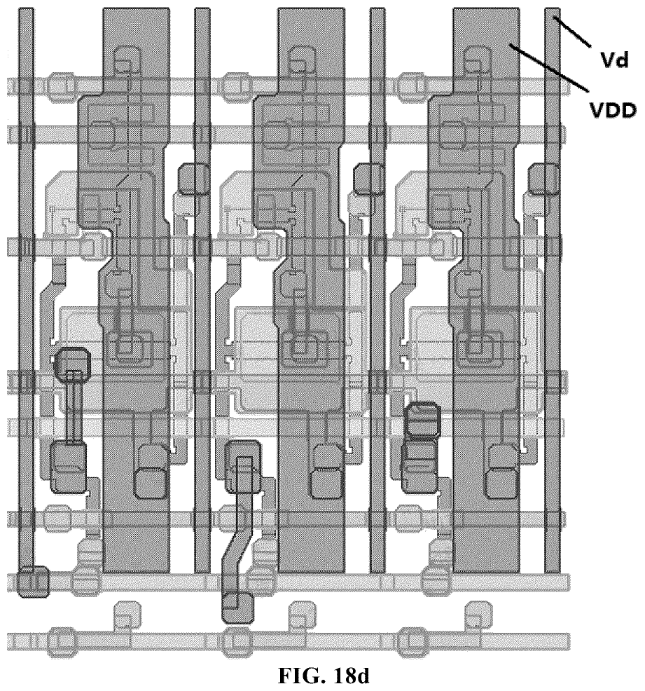

Illustratively, FIGS. 18a to 18d are layout diagrams showing a preparation process of the pixel drive circuit 21 shown in FIGS. 13 to 17. As shown in FIG. 18a, a semiconductor layer 06 is formed. As shown in FIG. 18b, a second conductive layer 02 is formed on the semiconductor layer 06. As shown in FIG. 18c, a third conductive layer 03 and a fourth conductive layer 04 are sequentially formed on the second conductive layer 02. As shown in FIG. 18d, a fifth conductive layer 05 is formed on the fourth conductive layer 04.

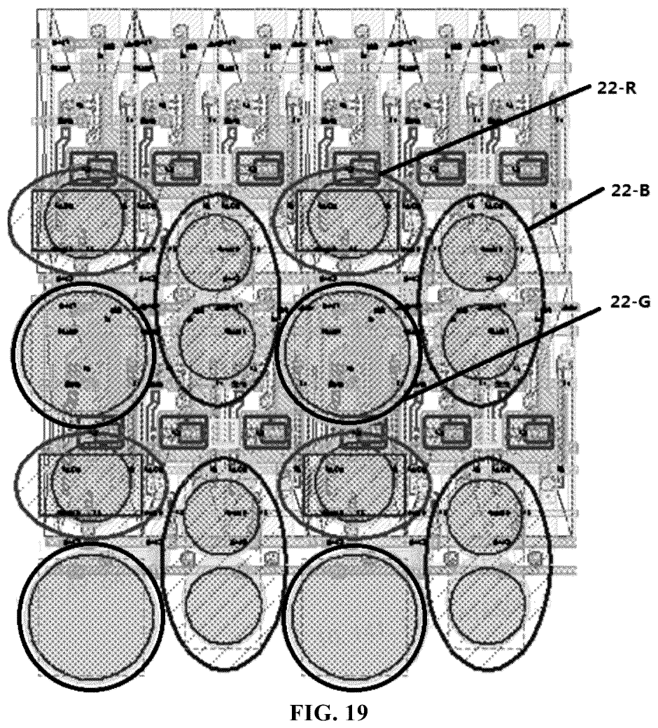

The pixel drive circuit 21 in the above example may be applied to the pixel arrangement shown in FIG. 3, 5 or 6. FIG. 19 is a layout diagram of pixel units according to an embodiment of the present disclosure. As shown in FIG. 19, the pixel drive circuit 21 shown in FIG. 18d is specifically applied to the pixel arrangement shown in FIG. 3.

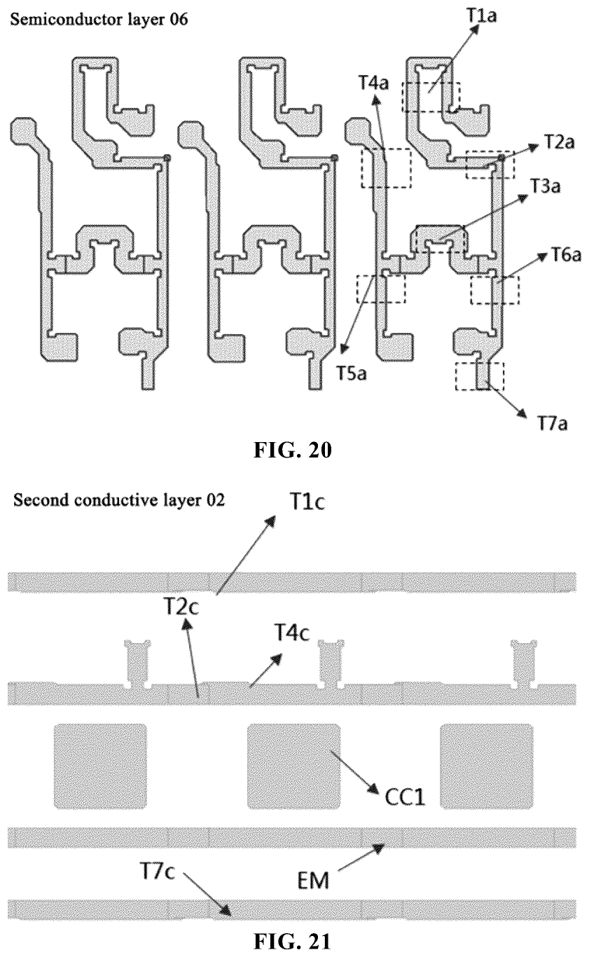

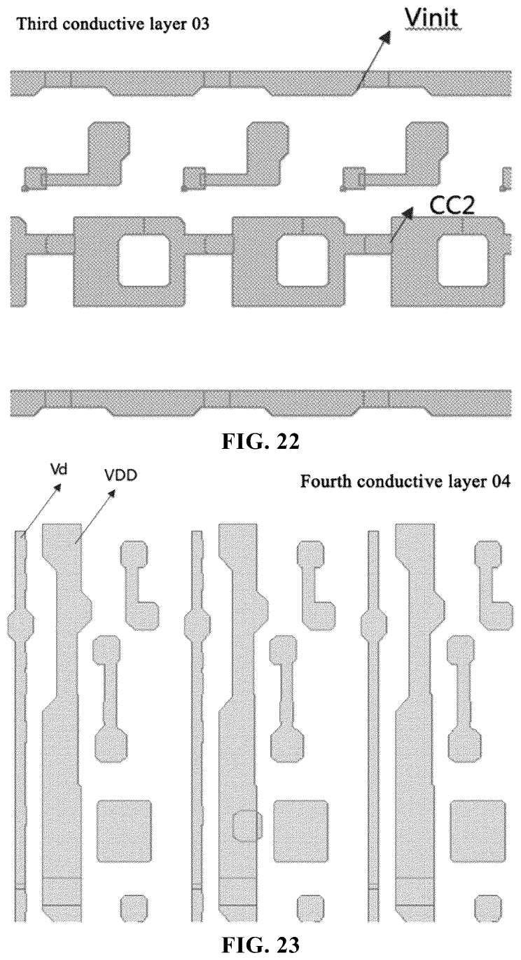

In another possible implementation, taking a 7T1C pixel drive circuit 21 as an example, FIG. 20 is a layout diagram of a semiconductor layer 06 according to an embodiment of the present disclosure, FIG. 21 is a layout diagram of a second conductive layer 02 according to an embodiment of the present disclosure, FIG. 22 is a layout diagram of a third conductive layer 03 according to an embodiment of the present disclosure, and FIG. 23 is a layout diagram of a fourth conductive layer 04 according to an embodiment of the present disclosure.

As shown in FIG. 20, an active layer T1a of the first reset transistor T1, an active layer T2a of the threshold compensation transistor T2, an active layer T3a of the drive transistor T3, an active layer T4a of the data write transistor T4, an active layer T5a of the first emission control transistor T5, an active layer T6a of the second emission control transistor T6, and an active layer T7a of the second reset transistor T7 are all located in the semiconductor layer 06.

As shown in FIG. 21, a gate T1c of the first reset transistor T1, a gate T2c of the threshold compensation transistor T2, a gate T4c of the data write transistor T4, a gate T7c of the second reset transistor T7, a first plate CC1 of the storage capacitor Cst, and a gate of the first emission control transistor T5, a gate of the second emission control transistor T6, a first emission control signal line EM1, and a second emission control signal line EM2 are all located in the second conductive layer 02. The gate of the first emission control transistor T5, the gate of the second emission control transistor T6, the first emission control signal line EM1, and the second emission control signal line EM2 form an integral structure (EM in FIG. 21).

Illustratively, the gate T1c of the first Reset transistor T1 and the first reset control signal line Reset1 (the control signal line of the first reset transistor T1) form an integral structure (T1c in FIG. 21); the gate T2c of the threshold compensation transistor T2 and the second scanning signal line Ga2 (the control signal line of the threshold compensation transistor T2) form an integral structure (T2c in FIG. 21); the gate T4c of the data write transistor T4 and the first scanning signal line Ga1 (the control signal line of the data write transistor T4) form an integral structure (T4c in FIG. 21); and the gate T7c of the second reset transistor T7 and the second reset control signal line Reset2 (the control signal line of the second reset transistor T7) form an integral structure (T7c in FIG. 21). Compared with a structure with layered signal lines and gates, this embodiment can save one mask layer, improve the process efficiency and save the process cost.

As shown in FIG. 22, a gate of the drive transistor T3, a second plate CC2 of the storage capacitor Cst, a signal line drawn from the first reset power terminal Vinit1 and electrically connected to the source of the first reset transistor T1, and a signal line drawn from the second reset power terminal Vinit2 and electrically connected to the source of the second reset transistor T7 are all located in the third conductive layer 03. The gate of the drive transistor T3 and the second plate CC2 of the storage capacitor Cst form an integral structure (CC2 in FIG. 22). A signal line drawn from the first reset power terminal Vinit1 and electrically connected to the source of the first reset transistor T1, and a signal line drawn from the second reset power terminal Vinit2 and electrically connected to the source of the second reset transistor T7 form an integral structure (Vinit in FIG. 22).

As shown in FIG. 23, a data line Vd is located in the fifth conductive layer 05, and a signal line drawn from the first power voltage terminal VDD and electrically connected to the first plate CC1 of the storage capacitor Cst and a source of the first emission control transistor T5 (i.e., the source of the first emission control transistor T5) is also located in the fifth conductive layer 05.

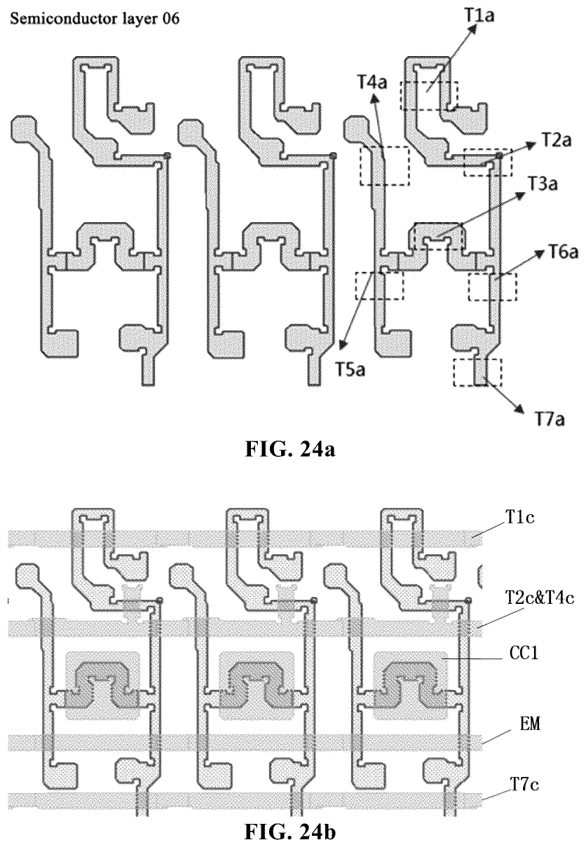

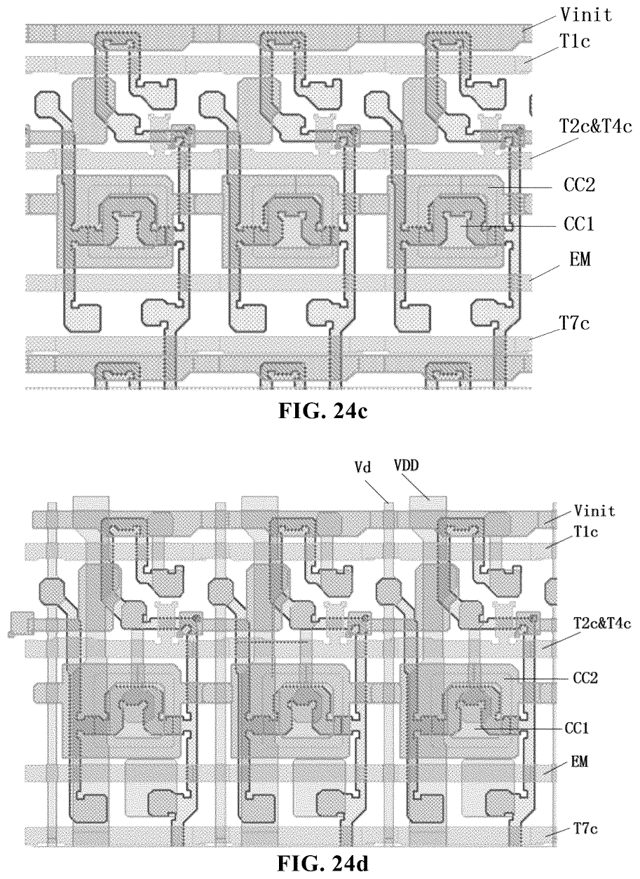

Illustratively, FIGS. 24a to 24d are layout diagrams showing a preparation process of the pixel drive circuit 21 shown in FIGS. 20 to 23. As shown in FIG. 24a, a semiconductor layer 06 is formed. As shown in FIG. 24b, a second conductive layer 02 is formed on the semiconductor layer 06. As shown in FIG. 24c, a third conductive layer 03 is formed on the second conductive layer 02. As shown in FIG. 24d, a fourth conductive layer 04 is formed on the third conductive layer 03.

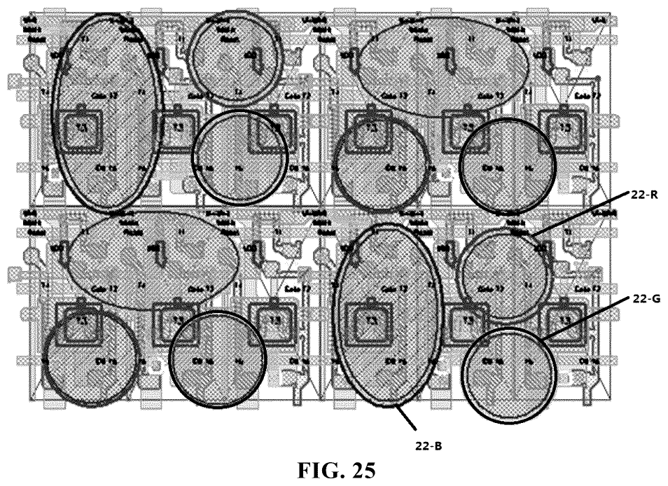

The pixel drive circuit 21 in the above example may be applied to the pixel arrangement shown in FIG. 9. FIG. 25 is another layout diagram of pixel units according to an embodiment of the present disclosure. As shown in FIG. 25, the pixel drive circuit 21 shown in FIG. 24d is specifically applied to the pixel arrangement shown in FIG. 9.

In some embodiments and in combination with the above embodiments, orthographic projections of first electrodes of at least part of the light-emitting devices on the base substrate 1 each have a circular contour shape.

Illustratively, the orthographic projection of the first electrode of each light-emitting device on the base substrate 1 may have a circular shape, so as to improve the wiring arrangement of the real RGB pixel structure.

In some embodiments and in combination with the above embodiments, a ratio of a size of the pixel opening of each light-emitting device in a column direction to a size thereof in a row direction is in a range from 1:1 to 1:3.

Illustratively, the ratio of the size of the pixel opening of each light-emitting device in the column direction to the size thereof in the row direction is 1:1, so that it is determined that the orthographic projection of the pixel opening of the light-emitting device on the base substrate 1 has a circular contour shape.

Illustratively, the orthographic projection of the pixel opening of the light-emitting device on the base substrate 1 has a symmetrical contour shape enclosed by a plurality of arc-shaped parts and straight sides alternately arranged, and at least two of the arc-shaped parts correspond to a same angle. The ratio of the size of the pixel opening of each light-emitting device in the column direction to the size thereof in the row direction is any one of 1:1 to 1:3, excluding 1:1, so that it is determined that the orthographic projection of the pixel opening of the light-emitting device on the base substrate 1 has an elliptical contour shape. In this case, the ratio of the size of the pixel opening of each light-emitting device in the column direction to the size thereof in the row direction is a ratio of the minor axis to the major axis of the ellipse.

In some embodiments, the subpixel 22 includes a plurality of light-emitting devices; and a distance between light-emitting devices in different subpixels 22 is greater than a distance between the plurality of light-emitting devices in the subpixel 22 including the light-emitting devices.

Illustratively, as shown in FIG. 3, the blue subpixel 22-B includes two blue light-emitting devices, B1 and B2, and, for example, a distance between the red light-emitting device R and the green light-emitting device G1 is greater than a distance between the blue light-emitting devices B1 and B2. Here, the distance between the red light-emitting device R and the green light-emitting device G1 may be understood as a distance between geometric centers of pixel openings of the red light-emitting device R and the green light-emitting device G1. The distance between the blue light-emitting devices B1 and B2 may be understood as a distance between geometric centers of pixel openings of the blue light-emitting devices B1 and B2. In the embodiment of the present disclosure, the blue subpixel 22-B is divided into two circular blue light-emitting devices, because the pixel opening of the blue subpixel 22-B has a larger area, and by dividing it into two parts, the pixel opening of the blue light-emitting device B1 (or B2) is not significantly different from the pixel opening of the red light-emitting device R or the green light-emitting device G1, so that the four light-emitting devices are closely distributed, thereby achieving a higher aperture ratio.

Similarly, as shown in FIG. 5 or 6, for the green subpixel 22-G, the green subpixel 22-G includes two green light-emitting devices, G1 and G2, and, for example, a distance between the red light-emitting device R and the green light-emitting device G1 is greater than a distance between the green light-emitting devices G1 and G2. Here, the green subpixel 22-G is divided into two circular green light-emitting devices, because the pixel opening of the green subpixel 22-G has a larger area, and by dividing it into two parts, the pixel opening of the green light-emitting device G1 (or G2) is not significantly different from the pixel opening of the red light-emitting device R or the blue light-emitting device B1, so that the four light-emitting devices are closely distributed, thereby achieving a higher aperture ratio.

In some embodiments, the emission layer of each light-emitting device is on a side of the pixel defining layer PDL facing away from the first electrode; and orthographic projections of emission layers of different light-emitting devices on the base substrate are at least partially overlapped with each other.

In some embodiments, orthographic projections of emission layers of at least part of the light-emitting devices on the base substrate each have a circular contour shape; or, orthographic projections of emission layers of at least part of the light-emitting devices on the base substrate each have a symmetrical contour shape enclosed by a plurality of arc-shaped parts and straight sides alternately arranged, and at least two of the arc-shaped parts correspond to a same angle, which may include, for example, an elliptical shape, a rounded rectangle shape, a rounded polygonal shape, or the like, so that the diffraction image of the product has an approximately circular shape, which can reduce color separation in the product and improve the display effect.

In some embodiments, the display substrate further includes a spacer; and the spacer is on a side of the pixel defining layer close to the emission layer, and configured to support a fine metal mask (FMM) and prevent damage.

In some embodiments, for the plurality of pixel units arranged in an array, one spacer is correspondingly provided every 2 to 3 rows of the pixel units and/or every 3 to 5 columns of the pixel units.

Illustratively, for the plurality of pixel units arranged in an array, one spacer is correspondingly provided every 3×4 pixel units, which can not only ensure the supporting strength, but also save materials.

In some embodiments, an orthographic projection of each color filter block on the base substrate covers an orthographic projection of a light-emitting device corresponding to the color filter block on the base substrate.

In some embodiments, a distance between a contour edge of the orthographic projection of the color filter block on the base substrate and a contour edge of the orthographic projection of the light-emitting device corresponding to the color filter block on the base substrate is in a range from 1.5 μm to 10.5 μm.

In addition, an embodiment of the present disclosure further provides a display apparatus, including the display substrate as described in any of the above embodiments. The display apparatus may be, for example, a tablet, a monitor, a laptop, a digital album, a vehicle-mounted device or any other product having a display function. Other essential components of the display apparatus are regarded as present by those skilled in the art, which are not described herein and should not be construed as limiting the present disclosure.

It will be appreciated that the above implementations are merely exemplary implementations for the purpose of illustrating the principle of the present disclosure, and the present disclosure is not limited thereto. Various modifications and improvements can be made by those skilled in the art without departing from the spirit and essence of the disclosure. Accordingly, all of the modifications and improvements also fall into the protection scope of the present disclosure.

1. A display substrate, comprising a base substrate, a plurality of pixel units arranged in an array on the base substrate, and a color filter layer on a side of the pixel units facing away from the base substrate; wherein
each pixel unit comprises a plurality of pixel drive circuits and a plurality of light-emitting devices on the base substrate, with each light-emitting device electrically connected to one of the pixel drive circuits to form one subpixel; and the color filter layer comprises a plurality of color filter blocks, with each color filter block corresponding to one of the light-emitting devices; and
orthographic projections of pixel openings of at least part of the light-emitting devices on the base substrate each have a circular contour shape; and/or, orthographic projections of pixel openings of at least part of the light-emitting devices on the base substrate each have a symmetrical contour shape enclosed by a plurality of arc-shaped parts and straight sides alternately arranged, and at least two of the arc-shaped parts correspond to a same angle.

2. The display substrate according to claim 1, wherein a plurality of subpixels are provided, comprising a first subpixel, a second subpixel, and a third subpixel; the first subpixel comprises a first light-emitting device; the second subpixel comprises a second light-emitting device; and the third subpixel comprises a third light-emitting device and a fourth light-emitting device; and
for the plurality of pixel units arranged in an array, first light-emitting devices and second light-emitting devices are alternately arranged in a column direction to form multiple columns of first light-emitting device groups; and third light-emitting devices and fourth light-emitting devices are alternately arranged in the column direction to form multiple columns of second light-emitting device groups.

3. The display substrate according to claim 2, wherein orthographic projections of pixel openings of the first, second, third and fourth light-emitting devices on the base substrate each have a circular contour shape, and/or
wherein for one of the pixel units, the first subpixel has an aperture ratio A, the second subpixel has an aperture ratio B, and the third subpixel has an aperture ratio C; and A:B:C is one of 1:(1.7 to 2.2):(1.4 to 2).

4-6. (canceled)

7. The display substrate according to claim 1, wherein a plurality of subpixels are provided, comprising a first subpixel, a second subpixel, and a third subpixel; the first subpixel comprises a first light-emitting device; the second subpixel comprises a second light-emitting device and a fifth light-emitting device; and the third subpixel comprises a third light-emitting device and a fourth light-emitting device;
for the plurality of pixel units arranged in an array, first light-emitting devices and second subpixels are alternately arranged in a column direction to form multiple columns of first light-emitting device groups; and third light-emitting devices and fourth light-emitting devices are alternately arranged in the column direction to form multiple columns of second light-emitting device groups; and
an extension line of a connection line between center points of the second light-emitting device and the fifth light-emitting device forms an angle in a range of 0° to 90° with an extension line of a connection line between center points of the third light-emitting device and the fourth light-emitting device.

8. The display substrate according to claim 7, wherein orthographic projections of pixel openings of the first, second, third, fourth and fifth light-emitting devices on the base substrate each have a circular contour shape.

9. The display substrate according to claim 2, wherein the display substrate further comprises a first conductive layer on a side of the pixel drive circuits facing away from the base substrate, and a pixel defining layer on a side of the first conductive layer facing away from the base substrate;
each light-emitting device comprises a pixel opening penetrating through the pixel defining layer, and a first electrode formed on a side of the pixel defining layer close to the pixel drive circuit, and an emission layer and a second electrode at least in the pixel opening;
the first conductive layer comprises the first electrode of each light-emitting device; and
for the third subpixel, the first electrode of the third light-emitting device is electrically connected to the first electrode of the fourth light-emitting device.

10. The display substrate according to claim 9, wherein the first electrode of the third light-emitting device and the first electrode of the fourth light-emitting device are connected into an integral structure, or
wherein the first electrode of the third light-emitting device is disconnected from the first electrode of the fourth light-emitting device; and
for the third subpixel, the pixel drive circuit comprises a drive transistor and a first connection electrode electrically connected to the drive transistor; the first connection electrode comprises a first main body part, and a first branch part and a second branch part each electrically connected to the first main body part; and the first branch part is electrically connected to the first electrode of the third light-emitting device, while the second branch part is electrically connected to the first electrode of the fourth light-emitting device.

11. (canceled)

12. The display substrate according to claim 7, wherein the display substrate further comprises a first conductive layer on a side of the pixel drive circuits facing away from the base substrate, and a pixel defining layer on a side of the first conductive layer facing away from the base substrate;
each light-emitting device comprises a pixel opening penetrating through the pixel defining layer, and a first electrode formed on a side of the pixel defining layer close to the pixel drive circuit, and an emission layer and a second electrode at least in the pixel opening;
the first conductive layer comprises the first electrode of each light-emitting device; and
for the third subpixel, the first electrode of the third light-emitting device is electrically connected to the first electrode of the fourth light-emitting device,
wherein for the second subpixel, the first electrode of the second light-emitting device is electrically connected to the first electrode of the fifth light-emitting device.

13. The display substrate according to claim 12, wherein the first electrode of the second light-emitting device and the first electrode of the fifth light-emitting device are connected into an integral structure, or
wherein the first electrode of the second light-emitting device is disconnected from the first electrode of the fifth light-emitting device; and
for the second subpixel, the pixel drive circuit comprises a drive transistor and a second connection electrode electrically connected to the drive transistor; the second connection electrode comprises a second main body part, and a third branch part and a fourth branch part each electrically connected to the second main body part; and the third branch part is electrically connected to the first electrode of the second light-emitting device, while the fourth branch part is electrically connected to the first electrode of the fifth light-emitting device.

14. (canceled)

15. The display substrate according to claim 1, wherein the plurality of pixel units comprise a first pixel unit and a second pixel unit, and first pixel units and second pixel units are alternately arranged in each of a row direction and a column direction;
each of the first pixel unit and the second pixel unit comprises a first subpixel, a second subpixel, and a third subpixel; the first subpixel comprises a first light-emitting device, the second subpixel comprises a second light-emitting device, and the third subpixel comprises a third light-emitting device;
for the first pixel unit, the first light-emitting device and the second light-emitting device are located in a same column, which is a column adjacent to a column where the third light-emitting device is located;
for the second pixel unit, the first light-emitting device and the second light-emitting device are located in a same row, which is a row adjacent to a row where the third light-emitting device is located; and
a connection line between center points of the first and second light-emitting devices in the first pixel unit is a first line segment, while a connection line between center points of the first and second light-emitting devices in the second pixel unit is a second line segment; and an extending direction of the first line segment is perpendicular to an extending direction of the second line segment.

16. The display substrate according to claim 15, wherein orthographic projections of pixel openings of the first and second light-emitting devices on the base substrate each have a circular contour shape; and
an orthographic projection of a pixel opening of the third light-emitting device on the base substrate has an elliptical contour shape.

17. The display substrate according to claim 16, wherein for the first pixel unit, an extending direction of the first line segment is perpendicular to an extending direction of a minor axis corresponding to the contour of the pixel opening of the third light-emitting device; and
for the second pixel unit, an extending direction of the second line segment is perpendicular to the extending direction of the minor axis corresponding to the contour of the pixel opening of the third light-emitting device.

18. The display substrate according to claim 1, wherein the display substrate further comprises a semiconductor layer on the base substrate, a second conductive layer on a side of the semiconductor layer facing away from the base substrate, a third conductive layer on a side of the second conductive layer facing away from the base substrate, and a fourth conductive layer on a side of the second conductive layer close to the third conductive layer;
each pixel drive circuit comprises at least a plurality of thin film transistors and a storage capacitor;
an active layer of each thin film transistor is located in the semiconductor layer;
gates of at least part of the thin film transistors and a first plate of the storage capacitor are located in the second conductive layer;
a second plate of the storage capacitor is located in the third conductive layer; and
control signal lines of at least part of the thin film transistors are located in the fourth conductive layer.

19. The display substrate according to claim 1, wherein orthographic projections of first electrodes of at least part of the light-emitting devices on the base substrate each have a circular contour shape.

20. The display substrate according to claim 1, wherein a ratio of a size of the pixel opening of each light-emitting device in a column direction to a size of the pixel opening in a row direction is in a range from 1:1 to 1:3.

21. The display substrate according to claim 1, wherein each subpixel comprises a plurality of light-emitting devices; and
a distance between light-emitting devices in different subpixels is greater than a distance between the plurality of light-emitting devices in the subpixel comprising the light-emitting devices.

22. The display substrate according to claim 9, wherein the emission layer of each light-emitting device is on a side of the pixel defining layer facing away from the first electrode; and orthographic projections of emission layers of different light-emitting devices on the base substrate are at least partially overlapped with each other,
wherein orthographic projections of emission layers of at least part of the light-emitting devices on the base substrate each have a circular contour shape; or, orthographic projections of emission layers of at least part of the light-emitting devices on the base substrate each have a symmetrical contour shape enclosed by a plurality of arc-shaped parts and straight sides alternately arranged, and at least two of the arc-shaped parts correspond to a same angle.

23. (canceled)

24. The display substrate according to claim 1, wherein the display substrate further comprises a spacer; and the spacer is on a side of the pixel defining layer close to the emission layer,
wherein for the plurality of pixel units arranged in an array, one spacer is correspondingly provided every 2 to 3 rows of the pixel units and/or every 3 to 5 columns of the pixel units.

25. (canceled)

26. The display substrate according to claim 1, wherein an orthographic projection of each color filter block on the base substrate covers an orthographic projection of a light-emitting device corresponding to the color filter block on the base substrate,
wherein a distance between a contour edge of the orthographic projection of the color filter block on the base substrate and a contour edge of the orthographic projection of the light-emitting device corresponding to the color filter block on the base substrate is in a range from 1.5 μm to 10.5 μm.

27. (canceled)

28. A display apparatus, comprising the display substrate according to claim 1.
